(19) United States
(12) Patent Application Publication
(10) Pub. No.: US 2013/0285057 A1
(43) Pub. Date: Oct. 31, 2013

(54) SEMICONDUCTOR DEVICE

(71) Applicant: Renesas Electronics Corporation, Kawasaki-shi (JP)

(72) Inventor: Yasushi ISHII, Tokyo (JP)

(21) Appl. No.: 13/924,175

(22) Filed: Jun. 21, 2013

Related U.S. Application Data
(63) Continuation of application No. 12/239,809, filed on Sep. 28, 2008.

(30) Foreign Application Priority Data
Oct. 22, 2007 (JP) JP2007-274216

(51) Int. Cl. H01L 23/00

(52) U.S. Cl. CPC H01L 24/06
USPC 257/48; 257/774; 257/758

(57) ABSTRACT

Increase in the chip size of a semiconductor device is suppressed. The semiconductor device includes: circuit vias provided in an interlayer insulating film between upper and lower wiring layers and coupling these wiring layers together; a planar ring-shaped protecting via that is provided in the interlayer insulating film under an electrode pad and one side of which is coupled with the electrode pad; a protecting wiring layer comprised of a wiring layer coupled only with the other side of the protecting via; and a semiconductor element provided over the principal surface of a semiconductor substrate under the protecting wiring layer. The lower part of the electrode pad whose surface is exposed is encircled with the protecting via and the protecting wiring layer. The width of the protecting via is equal to or larger than the width of each circuit via.

### CROSS-REFERENCE TO RELATED APPLICATIONS

The disclosure of Japanese Patent Application No. 2007-274216 filed on Oct. 22, 2007 including the specification, drawings and abstract is incorporated herein by reference in its entirety.

### BACKGROUND OF THE INVENTION

The present invention relates to semiconductor devices and in particular to a technology effectively applicable to a semiconductor device having an electrode pad provided above a semiconductor element.

An electrode pad is electrically coupled with a semiconductor element, such as MISFET (Metal Insulator Semiconductor Field Effect Transistor), through a contact, a via, and a wiring layer and is provided over a semiconductor substrate (semiconductor wafer, composing semiconductor chips). This electrode pad is used for coupling at the time of a wafer probing test and wire bonding coupling at the time of assembling.

In general, conventionally, no electrode pad used to be provided over an active area where a semiconductor element is formed. A reason for this is the prevention of the following: a crack may be produced under an electrode pad due to pressure applied during probing to the electrode pad or the like and a semiconductor element provided under an electrode pad is damaged and the characteristics of the semiconductor element are degraded.

However, the following has taken place as the functions provided in a semiconductor integrated circuit are increased as the result of microminiaturization of an semiconductor element and thus the number of required electrode pads is increased: the necessity for PAA (PAD on Active Area) in which an electrode pad is disposed over an semiconductor element formed in an active area has arisen. The PAA makes it possible to suppress increase in chip size.

The prevent inventors investigated into the related art from the following points of view based on the result of the invention: a point of view of using PAA for the suppression of increase in chip size; and a point of view of encircling the area under an electrode pad with a protecting via functioning as a protection material for the prevention of cracking and a protecting wiring layer positioned thereunder. As a result, with respect to the point of view of encircling with a protecting via and a protecting wiring layer, Japanese Unexamined Patent Publication No. 2006-165419 (Patent Document 1) was retrieved. The subject matter of Patent Document 1 is to prevent the progress of cracking directly under an electrode pad to enhance the reliability of a semiconductor device as a whole. The document does not describe that increase in chip size is suppressed by use of PAA.

### Patent Document 1

Japanese Unexamined Patent Publication 2006-165419

### SUMMARY OF THE INVENTION

When PAA is not used for a semiconductor device, the chip size is increased with increase in the number of electrode pads. The necessity for PAA as an effective means for the prevention of increase in chip size has arisen. This is because use of PAA makes it possible to dispose a semiconductor element under an electrode pad.

Even when PAA is applied to a semiconductor device, development, evaluation, and analysis may be required on a process-by-process basis because the wiring structure or the like differs from semiconductor device to semiconductor device. For this reason, it is desirable that PAA can be easily applied to a semiconductor device from any process. PAA not only has to be simply so formed that an electrode pad is provided above a semiconductor element formed in an active area. PAA is also required to prevent cracking from being caused under an electrode pad by pressure applied at the time of probing to the electrode pad or on other like occasions and to prevent a semiconductor element provided under an electrode pad from being damaged and degraded in characteristics.

An object of the invention is to provide a technology that makes it possible to suppress increase in the chip size of a semiconductor device.

Another object of the invention is to provide a technology that makes it possible to enhance the reliability of a semiconductor device in which an electrode pad is disposed above a semiconductor element.

The above and other objects and novel features of the invention will be apparent from the description in this specification and the accompanying drawings.

The following is a brief description of the gist of the representative elements of the invention laid open in this application.

In the description of an embodiment of the invention, the following case will be taken as an example: a case where the invention is applied to a semiconductor device having: a circuit via provided in an interlayer insulating film between upper and lower wiring layers and coupling the wiring layers; a protecting via which is provided in the interlayer insulating film under an electrode pad and one side of which is coupled with the electrode pad; a protecting wiring layer comprised of a wiring layer coupled with only the other side of the protecting via; and a semiconductor element provided over the principal surface of a semiconductor substrate under the protecting wiring layer. The width of the protecting via is equal to or larger than the width of the circuit via.

The following is a brief description of the gist of the effect obtained by the representative elements of the invention laid open in this application.

According to this embodiment, increase in the chip size of a semiconductor device can be suppressed.

### BRIEF DESCRIPTION OF THE DRAWINGS

FIG. 1 is a schematic diagram illustrating a plane of a semiconductor device in an embodiment of the invention;

FIG. 2 is a schematic diagram illustrating the section of the semiconductor device in FIG. 1 taken along line X-X;

FIG. 3 is a perspective schematic diagram illustrating the area A encircled with a broken line in the semiconductor device in FIG. 1;

FIG. 4 is a schematic diagram illustrating a substantial part of the semiconductor device in FIG. 2;

FIG. 5 is an explanatory drawing illustrating a case where a crack is produced in the semiconductor device in FIG. 4;

FIG. 6 is a schematic diagram illustrating a plane of a semiconductor device reviewed by the present inventors;

FIG. 7 is a schematic diagram illustrating the section of the semiconductor device in FIG. 6 taken along line X-X;

FIG. 8 is a schematic diagram illustrating a section of a semiconductor device in a manufacturing process in an embodiment of the invention;

FIG. 9 is a schematic diagram illustrating the section of the semiconductor device in the manufacturing process, following FIG. 8;

FIG. 10 is a schematic diagram illustrating the section of the semiconductor device in the manufacturing process, following FIG. 9;

FIG. 11 a schematic diagram illustrating the section of the semiconductor device in the manufacturing process, following FIG. 10;

FIG. 12 is a schematic diagram illustrating the section of the semiconductor device in the manufacturing process, following FIG. 11;

FIG. 13 is a schematic diagram illustrating the section of the semiconductor device in the manufacturing process, following FIG. 12;

FIG. 14 is a schematic diagram illustrating the section of the semiconductor device in the manufacturing process, following FIG. 13;

FIG. 15 is a schematic diagram illustrating the section of the semiconductor device in the manufacturing process, following FIG. 14;

FIG. 16 is a schematic diagram illustrating the section of the semiconductor device in the manufacturing process, following FIG. 15;

FIG. 17 is a schematic diagram illustrating the section of the semiconductor device in the manufacturing process, following FIG. 16;

FIG. 18 is a schematic diagram illustrating the section of the semiconductor device in the manufacturing process, following FIG. 17;

FIG. 19 is a schematic diagram illustrating the section of the semiconductor device in the manufacturing process, following FIG. 18;

FIG. 20 is a schematic diagram illustrating a plane of a substantial part of a semiconductor device in another embodiment of the invention;

FIG. 21 is a schematic diagram illustrating a plane of a substantial part of a semiconductor device in another embodiment of the invention;

FIG. 22 is a schematic diagram illustrating a plane of a substantial part of a semiconductor device in another embodiment of the invention;

FIG. 23 is a schematic diagram illustrating a plane of a substantial part of a semiconductor device in another embodiment of the invention;

FIG. 24 is a schematic diagram illustrating a plane of a substantial part of a semiconductor device in another embodiment of the invention;

FIG. 25 is a schematic diagram illustrating a plane of a substantial part of a semiconductor device in another embodiment of the invention;

FIG. 26 is a schematic diagram illustrating a plane of a substantial part of a semiconductor device in another embodiment of the invention;

FIG. 27 is a schematic diagram illustrating a plane of a substantial part of a semiconductor device in another embodiment of the invention;

FIG. 28 is a schematic diagram illustrating a plane of a substantial part of a semiconductor device in another embodiment of the invention;

FIG. 29 is a schematic diagram illustrating a plane of a substantial part of a semiconductor device in another embodiment of the invention;

FIG. 30 is a schematic diagram illustrating a plane of a substantial part of a semiconductor device in another embodiment of the invention;

FIG. 31 is a schematic diagram illustrating a plane of a substantial part of a semiconductor device in another embodiment of the invention;

FIG. 32 is a schematic diagram illustrating a plane of a substantial part of a semiconductor device in another embodiment of the invention;

FIG. 33 is a schematic diagram illustrating a plane of a substantial part of a semiconductor device in another embodiment of the invention;

FIG. 34 is a schematic diagram illustrating a plane of a substantial part of a semiconductor device in another embodiment of the invention;

FIG. 35 is a schematic diagram illustrating a section of a substantial part of a semiconductor device in another embodiment of the invention;

FIG. 36 is a schematic diagram illustrating a section of a substantial part of a semiconductor device in another embodiment of the invention;

FIG. 37 is a schematic diagram illustrating a plane of a substantial part of a semiconductor device in another embodiment of the invention;

FIG. 38 is a schematic diagram illustrating the section of the semiconductor device in FIG. 37 taken along line X-X;

FIG. 39 is a schematic diagram illustrating a section of a semiconductor device in a manufacturing process in another embodiment of the invention;

FIG. 40 is a schematic diagram illustrating the section of the semiconductor device in the manufacturing process, following FIG. 39;

FIG. 41 is a schematic diagram illustrating the section of the semiconductor device in the manufacturing process, following FIG. 40;

FIG. 42 is a schematic diagram illustrating the section of the semiconductor device in the manufacturing process, following FIG. 41;

FIG. 43 is a schematic diagram illustrating the section of the semiconductor device in the manufacturing process, following FIG. 42;

FIG. 44 is a schematic diagram illustrating the section of the semiconductor device in the manufacturing process, following FIG. 43;

FIG. 45 is a schematic diagram illustrating the section of the semiconductor device in the manufacturing process, following FIG. 44;

FIG. 46 is a schematic diagram illustrating the section of the semiconductor device in the manufacturing process, following FIG. 45;

FIG. 47 is a schematic diagram illustrating the section of the semiconductor device in the manufacturing process, following FIG. 46;

FIG. 48 is a schematic diagram illustrating a plane of a substantial part of a semiconductor device in another embodiment of the invention;

FIG. 49 is a schematic diagram illustrating the section of the semiconductor device in FIG. 48 taken along line X-X;

FIG. 50 is a schematic diagram illustrating a section of a semiconductor device in a manufacturing process in another embodiment of the invention;

FIG. 51 is a schematic diagram illustrating the section of the semiconductor device in the manufacturing process, following FIG. 50;

FIG. 52 is a schematic diagram illustrating the section of the semiconductor device in the manufacturing process, following FIG. 51;

FIG. 53 is a schematic diagram illustrating the section of the semiconductor device in the manufacturing process, following FIG. 52;

FIG. 54 is a schematic diagram illustrating the section of the semiconductor device in the manufacturing process, following FIG. 50;

FIG. 55 is a schematic diagram illustrating the section of the semiconductor device in the manufacturing process, following FIG. 54;

FIG. 56 is a schematic diagram illustrating a plane of a substantial part of a semiconductor device in another embodiment of the invention;

FIG. 57 is a schematic diagram illustrating the section of the semiconductor device in FIG. 56 taken along line X-X;

FIG. 58 is a schematic diagram illustrating a section of a semiconductor device in a manufacturing process in another embodiment of the invention;

FIG. 59 is a schematic diagram illustrating the section of the semiconductor device in the manufacturing process, following FIG. 58;

FIG. 60 is a schematic diagram illustrating the section of the semiconductor device in the manufacturing process, following FIG. 59;

FIG. 61 is a schematic diagram illustrating the section of the semiconductor device in the manufacturing process, following FIG. 60;

FIG. 62 is a schematic diagram illustrating the section of the semiconductor device in the manufacturing process, following FIG. 61;

FIG. 63 is a schematic diagram illustrating a section of a semiconductor device in another embodiment of the invention; and

FIG. 64 is a schematic diagram illustrating a section of a semiconductor device in another embodiment of the invention.

### DETAILED DESCRIPTION OF THE PREFERRED EMBODIMENTS

Hereafter, detailed description will be given to embodiments of the invention with reference to the drawings. In every drawing for explaining the embodiments, members having the same functions will be marked with the same reference numerals, and the repetitive description thereof may be omitted. Drawings for explaining the following embodiments may be hatched for making the configuration understandable even though the drawing is a plan view.

The embodiments of the invention will be described with semiconductor devices with a semiconductor integrated circuit (LSI) incorporated therein taken as examples. A peripheral circuit, such as input/output, or memory may be incorporated depending on use. The semiconductor integrated circuit and the like (hereafter, referred to as circuit) are formed by electrically coupling MISFET, a via, a wiring layer, or the like provided over the principal surface of a semiconductor chip (semiconductor substrate).

### First Embodiment

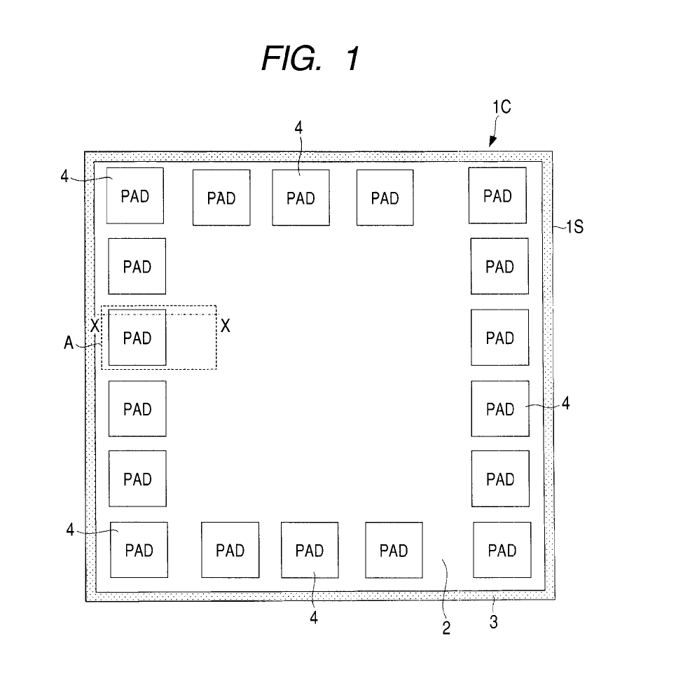

FIG. 1 is a schematic diagram illustrating a plane of a semiconductor device (semiconductor chip 1C) in this embodiment. Over the surface of a semiconductor substrate 1S comprising the semiconductor chip 1C, there are provided an element formation region 2 covered with a surface protective film (passivation film) and a peripheral region 3 around the periphery thereof. In the element formation region 2, MISFET and the like are formed and electrode pads (PADS) 4 electrically coupled therewith are provided as external terminals. The peripheral region 3 is provided with a means for preventing the ingress of moisture from the outside into the element formation region 2, including a margin area used when the semiconductor chips 1C are cut out of the semiconductor wafer.

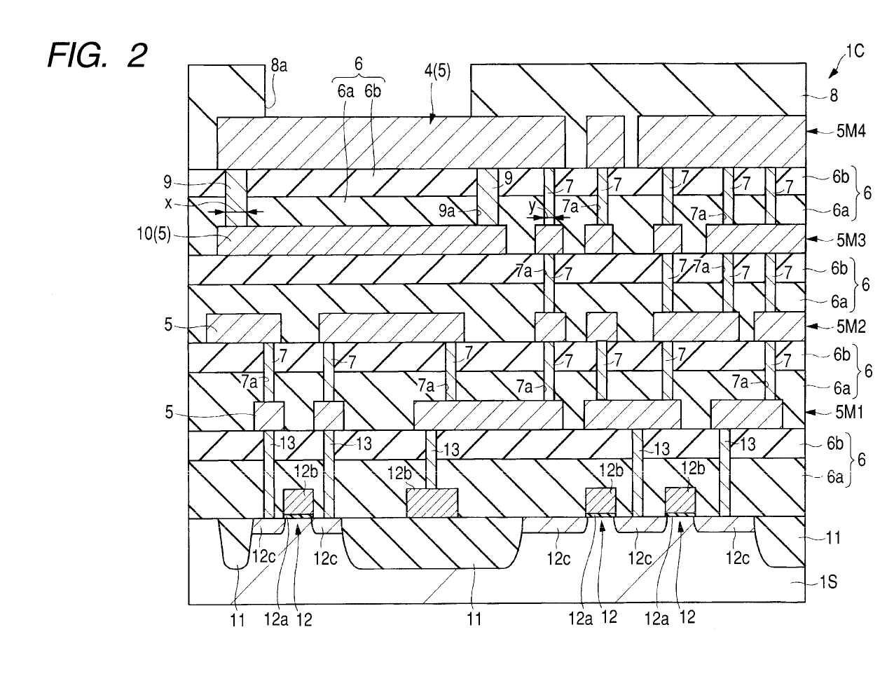

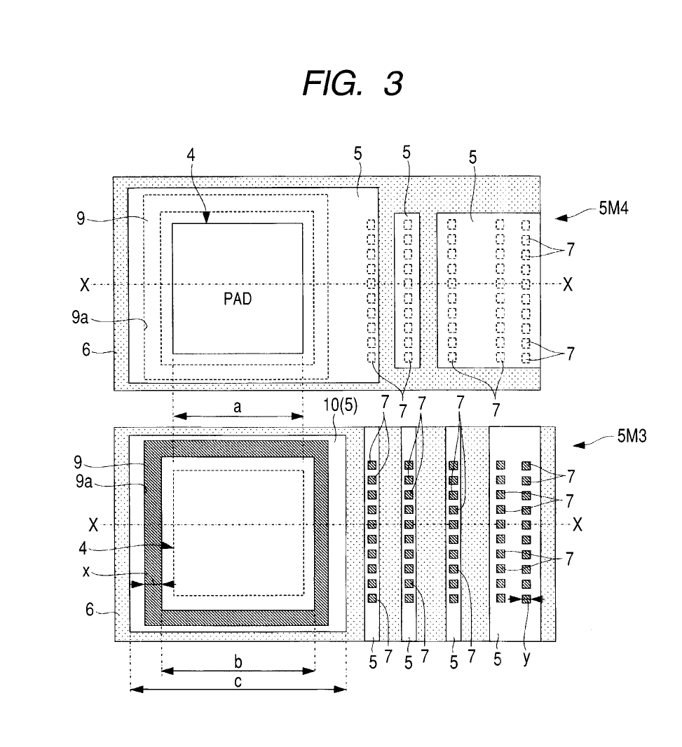

FIG. 2 is a schematic diagram illustrating the section of the semiconductor device in FIG. 1 taken along line X-X; and FIG. 3 is a perspective schematic diagram illustrating the area A encircled with a broken line in the semiconductor device in FIG. 1. In FIG. 3, the upper illustration and the lower illustration are respectively depicted with a focus on the uppermost wiring layer 5M4 and the wiring layer 5M3 thereunder. The drawing is depicted so that the dispositional relation between a planar ring-shaped protecting via 9, and an electrode pad 4 and a protecting wiring layer 10. In FIG. 3, for this reason, some members are omitted, and in the upper illustration, circuit vias 7a and the protecting via 9 under the wiring layer 5M4 are indicated by broken line.

As illustrated in FIG. 2, multiple wiring layers 5 are provided over the semiconductor substrate 1S with interlayer insulating films 6 in-between. In this embodiment, the wiring layers 5 are composed of four layers, and the first wiring layer 5M1 as the lowermost layer, the second wiring layer 5M2, the third wiring layer 5M3, and the fourth wiring layer 5M4 as the uppermost layer are laminated in the order. The electrode pad 4 is provided in part of the wiring layer 5M4 as the uppermost layer. These wiring layers 5 are formed of a material predominantly composed of, for example, Al (aluminum). The electrode pad 4 cited here refers to the wiring layer (wiring layer 5M4) as the uppermost layer whose surface is exposed by a pad opening 8a in a surface protective film 8.

The interlayer insulating films 6 electrically isolating the multiple wiring layers 5 are formed of an interlayer insulating film 6a and an interlayer insulating film 6b. The interlayer insulating film 6a uses an insulating film excellent in the property of filling for filling the area between wirings in the same layer. The interlayer insulating films 6 are formed of, for example, SiO₂ (silicon oxide).

The interlayer insulating film 6 between upper and lower wiring layers 5 (for example, between the wiring layer 5M3 and the wiring layer 5M4) of the multiple wiring layers 5 is provided with circuit vias 7. The circuit vias couple together the upper and lower wiring layers 5 (in the above example, the wiring layer 5M3 and the wiring layer 5M4). Each circuit via 7 is comprised of a hole 7a, for example, barrier metal, and high-melting point metal (for example, W (tungsten)) filling the interior of the hole 7a with the barrier metal in-between. The width y of each circuit via is equal to or larger than the minimum machining size and is, for example, 0.2 to 0.3 μm. The barrier metal is formed by laminating conductive films of, for example, Ti (titanium), TiN (titanium nitride), or the like.

Over the multiple wiring layers 5 that form the surface of the semiconductor chip 1C, there is provided the surface protective film 8 formed of, for example, polyimide. The surface protective film 8 is provided with the pad opening 8a so that the surface of the electrode pad 4 is exposed. As a result, the electrode pad 4 is used for coupling at the time of a wafer probing test, wire bonding coupling at the time of assembling, or for the other like purposes. In this embodiment, the following measure is taken in case of cracking in the interlayer insulating film 6 under the electrode pad 4 due to these coupling operations: the area where cracking will occur is encircled with protecting vias 9 and a protecting wiring layer 10 (wiring layer 5) thereunder to protect members forming a circuit.

Specifically, as illustrated in FIG. 3, the interlayer insulating film 6 under the electrode pad 4 (wiring layer 5M4) is provided with a planar ring-shaped protecting via 9 one side of which is coupled with the electrode pad 4. In this embodiment, the protecting via 9 is provided so that the planar ring shape thereof is rectangular. The protecting via 9 is comprised of: a trench 9a, for example, barrier metal, and high-melting point metal (for example, W (tungsten)) filling the interior of the trench 9a with the barrier metal in-between.

The width x of the protecting via 9 (the width of the trench 9a) is not smaller than the width y of each circuit via 7 and not larger than a width with which the high-melting point metal can be filled. The width x of the protecting via 9 is, for example, 0.6 μm. Of the multiple wiring layers 5, that positioned under the electrode pad 4 is provided with the protecting wiring layer 10 coupled only with the other side of the protecting via 9. The protecting wiring layer 10 is comprised of the wiring layer 5 and is thus formed of a material predominantly composed of, for example, Al (aluminum) similarly with the wiring layer 5. In the description of this embodiment, a case where the same materials as of the circuit vias 7 and the wiring layers 5 are respectively applied to the protecting via 9 and the protecting wiring layer 10 has been taken as an example. However, any other material is acceptable as long as the material is capable of protecting the circuit against cracking that occurs in the interlayer insulating film 6 under the electrode pad 4.

As illustrated in FIG. 1, the protecting via 9 and the protecting wiring layer 10 are provided under each of the multiple electrode pads 4 of the semiconductor chip 1C. That is, the protecting vias 9 are electrically isolated from one another and the protecting wiring layers 10 are also electrically isolated from one another so that short-circuiting will not occur between electrode pads 4. Therefore, the protecting wiring layers 10 cannot be used for the circuitry.

As mentioned above, the protecting via 9 and the protecting wiring layer 10 coupled only with the protecting via 9 encircle the interlayer insulating film 6 under the electrode pad 4 exposed in the pad opening 8a under the electrode pad 4. As a result, it is possible to prevent the occurrence of such a problem as extension of a crack beyond the encircled area to protect members comprising the circuit. A via comprising the circuit is described as circuit via 7 and is discriminated from the protecting via 9.

Over the principal surface of the semiconductor substrate 1S, there is provided an element isolation region 11 so that the active area is divided. The active area is provided with MISFET 12 as a semiconductor element comprising the circuit. Each MISFET 12 includes: an insulating film 12a forming a gate insulating film over the semiconductor substrate 1S; a conductive film 12b forming a gate electrode thereover; and a semiconductor region 12c forming a source and a drain, provided over the semiconductor substrate 1S under the side wall of the gate electrode.

In the gate electrode and the source and rain region, there is provided a silicide layer self-alignedly formed though the silicide layer is not shown in the drawings. The silicide layer is provided for the reduction of contact resistance and is formed of such a material as cobalt silicide or nickel silicide.

The principal surface of the semiconductor substrate 1S positioned under the protecting wiring layer 10 is also provided with MISFET 12. It is possible to provide a wiring layer 5, a diffusion layer (semiconductor region), and the like comprising the circuit under the protecting wiring layer 10. Conventionally, it used to be a common practice not to provide an active area (MISFET) under an electrode pad. The purpose for this is to prevent a semiconductor element provided under the electrode pad from being damaged due to pressure applied during probing to the electrode pad or the like and degraded in characteristics. However, the characteristics of the MISFET 12 under the protecting wiring layer 10 can be prevented from being influenced by pressure from the electrode pad 4. This is done by providing the protecting via 9 and the protecting wiring layer 10 under the electrode pad 4 as in this embodiment. As described in detail later, PAA (PAD on Active Area) in which an electrode pad 4 is disposed above such MISFET 12 can be achieved; therefore, increase in chip size can be suppressed. This suppression of increase in chip size makes it possible to suppress increase in the product cost of semiconductor devices as well. It is also possible to provide a wiring layer 5 as power supply wiring under the electrode pad 4.

In this embodiment, the element isolation region 11 is formed by the so-called STI (Shallow Trench Isolation) technique. That is, in the description of this embodiment, a case where the element isolation region is formed by forming a trench in the semiconductor substrate 1S and filling the trench with an insulating film, such as a silicon oxide film, is taken as an example. However, the element isolation region 11 may be formed by LOCOS, that is, by selectively thermally oxidizing the semiconductor substrate 1S.

As illustrated in FIG. 3, the protecting via 9 provided under the electrode pad 4 is in a ring shape (annular shape) on a plane and there is no discontinuity. The protecting via 9 is not coupled with the wiring layers 5 other than the electrode pad 4 and the protecting wiring layer 10 and is independent. The electrode pad 4 and the protecting via 9 are so disposed that the wiring layer 5 in the area exposed in the pad opening 8a in the surface protective film 8, that is, the electrode pad 4 is positioned inside the ring of the protecting via 9. In other words, the planar ring-shaped protecting via 9 is disposed outside the pad opening 8a exposing the electrode pad 4. As mentioned above, the following can be implemented by encircling the area under the pad opening 8a with the protecting via 9 and the protecting wiring layer 10: even when, for example, a probe pin is brought into contact with the electrode pad 4, the progress of cracking can be prevented. In this embodiment, further, the width of the protecting via 9 is equal to or larger than the width of each circuit via 7. Therefore, even when the circuit is microminiaturized and the width of each circuit via 7 is reduced, the progress of cracking can be prevented by the protecting via 9 whose thickness is ensured.

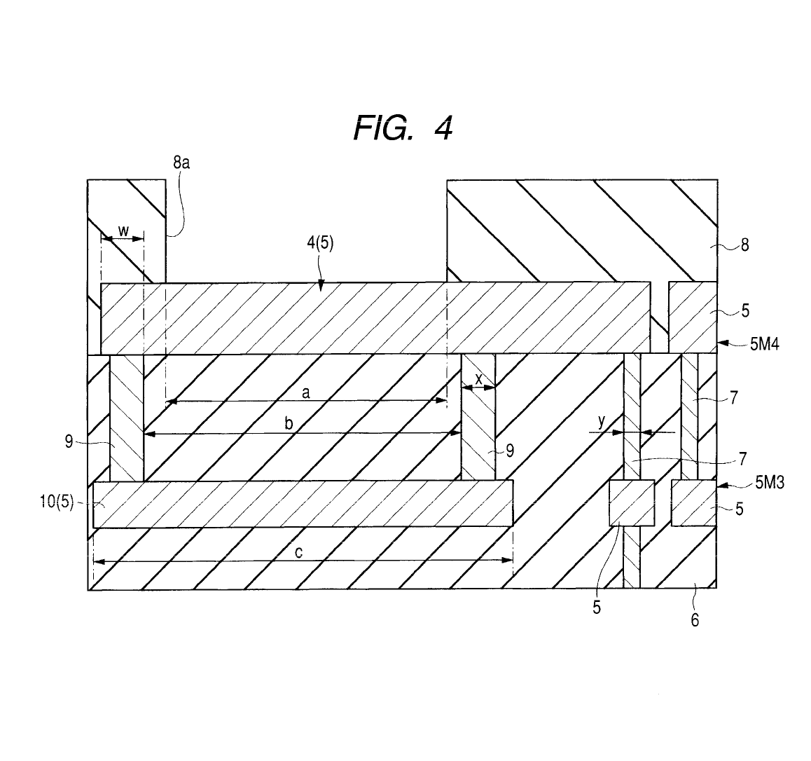

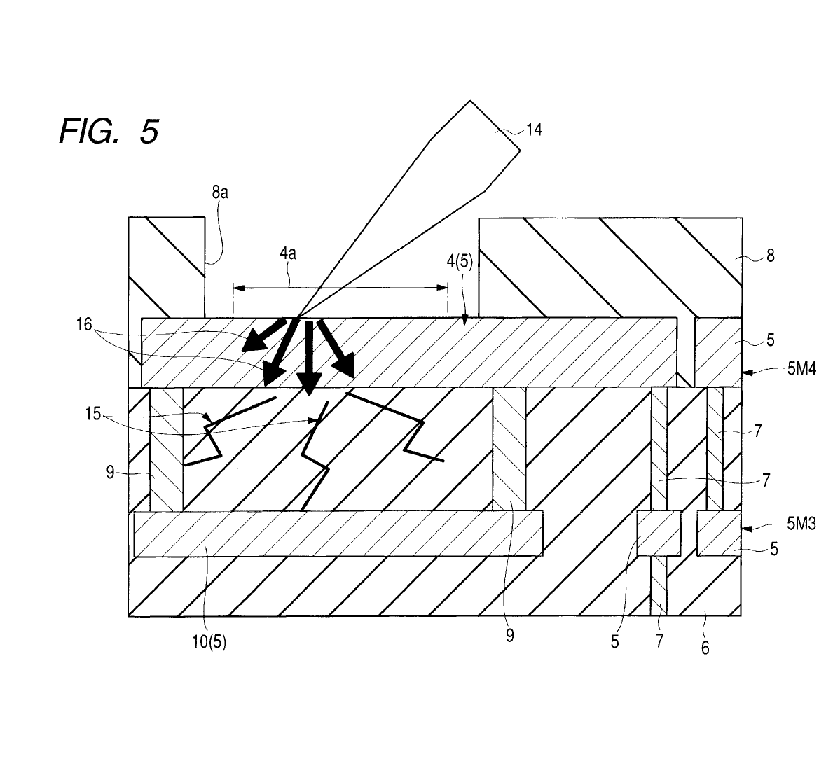

Description will be given to the disposition of the protecting via 9 and the protecting wiring layer 10 under the electrode pad 4 whose surface is exposed. FIG. 4 is a schematic diagram illustrating a substantial part of the semiconductor device in FIG. 2. FIG. 5 is an explanatory drawing illustrating a case where a probe pin 14 is brought into contact with the electrode pad 4 and a crack 15 is produced.

In this embodiment, parts of the following two layers of the multiple wiring layers 5 are respectively used as the electrode pad 4 and the protecting wiring layer 10: the wiring layer 5M4 as the uppermost layer and the wiring layer 5M3 thereunder. Between the electrode pad 4 and the protecting wiring layer 10, one side of the planar ring-shaped protecting via 9 is coupled with the electrode pad 4 and the other side is coupled with the protecting wiring layer 10. As a result, the area under the electrode pad 4 is encircled with the protecting via 9 and the protecting wiring layer 10. Therefore, the following can be implemented even when a probe pin 14 is brought into contact with the electrode pad 4 for the measurement of electrical characteristics and a crack 15 is produced as illustrated in FIG. 5: the crack 15 can be prevented from progressing beyond the area encircled with the protecting via 9 and the protecting wiring layer 10.

When the circuit is evaluated for electrical characteristics or wire bonding is carried out, for example, the following measure only has to be taken: the probe pin 14 or a bonding wire is brought into contact with the contact area 4a of the electrode pad 4. In this embodiment, as illustrated in FIG. 5, the planar ring-shaped protecting via 9 is so provided that the protecting via encircling the electrode pad 4 whose surface is exposed in the pad opening 8a. The protecting via 9 only has to be so provided that the following is implemented from the point of view of preventing the progress of a crack 15 produced due to contact of the probe pin 14 with the electrode pad 4: the protecting via 9 encircles the contact area 4a where the probe pin 14 is brought into contact with the electrode pad 4.

However, when the probe pin 14 is brought into contact with the boundary of the contact area 4a of the electrode pad 4, stress 16 can be spread as illustrated in FIG. 5. Therefore, to further prevent the progress of a crack 15, it is desirable to take the measure illustrated in FIG. 4. That is, it is desirable that the inside size b of the planar ring-shaped protecting via 9 should be equal to or larger than the size a of the pad opening 8a (pad electrode 4). It is desirable that the outside size c of the protecting wiring layer 10 should be equal to or larger than the inside size b of the planar ring-shaped protecting via 9. Further, it is desirable that the distance w from the end of the wiring layer 5 as the uppermost layer comprising the electrode pad 4 to the inside end of the planar ring-shaped protecting via 9 should be greater than zero. That is, it is desirable that the wiring layer 5 comprising the electrode pad and the protecting via 9 should overlap each other.

The progress of cracking can be prevented as illustrated in FIG. 5 in the interlayer insulating film (insulating film) 6 under the electrode pad 4. That is, the progress of a crack 15 in the horizontal direction (the right and left direction in the drawing) can be prevented by the protecting via 9 comprised of a tungsten film (metal film). The progress of a crack 15 in the downward direction (the downward direction in the drawing) can be prevented by the protecting wiring layer 10 comprised of an aluminum film (metal film). It can be thought that this is because the protecting via 9 and the protecting wiring layer 10 function as cushioning materials and a crack 15 progresses along the boundary between the metal films and the insulating film.

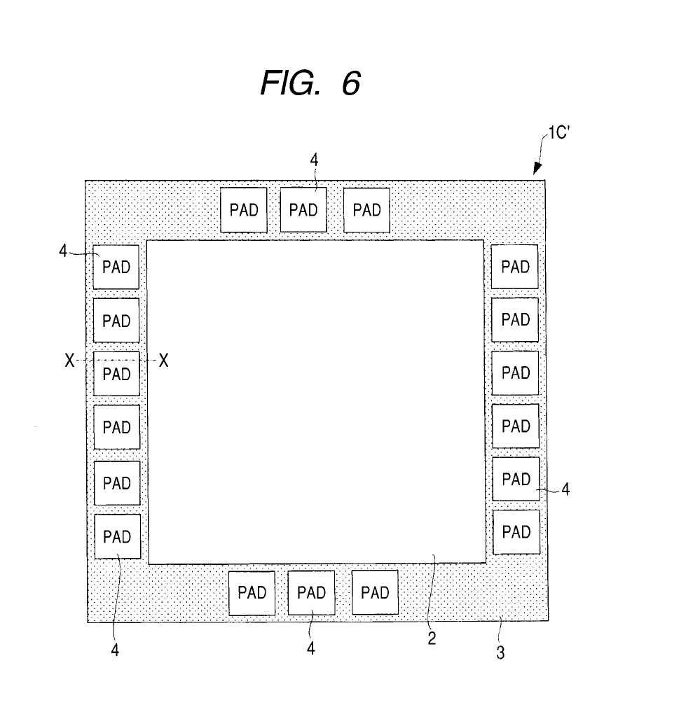

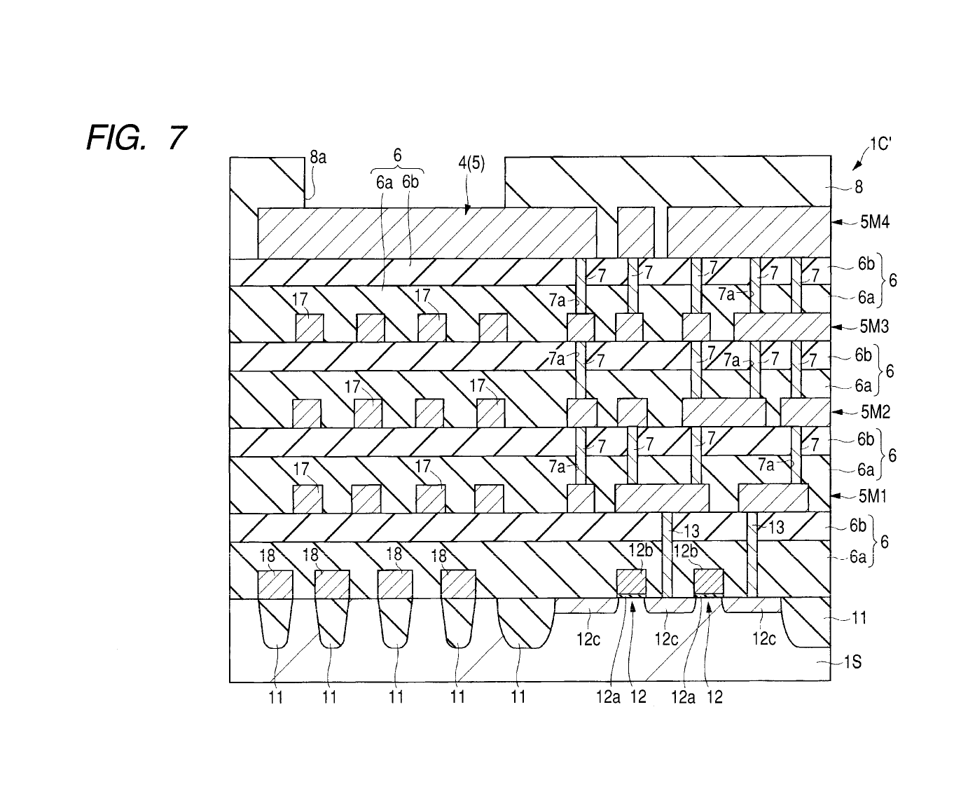

FIG. 6 is a schematic diagram illustrating a plane of a semiconductor device (semiconductor chip 1C′) reviewed by the present inventors, and FIG. 7 is a schematic diagram illustrating the section of the semiconductor device in FIG. 6 taken along line X-X. The circuitry of the semiconductor device in this embodiment and the circuitry of the semiconductor device reviewed by the present inventors have the same functions, and the size (area) of the element formation region 2 where the circuitry is formed is identical in FIG. 1 and in FIG. 6.

In the semiconductor chip 1C′ illustrated in FIG. 6 and FIG. 7, any member comprising the circuit is not disposed under the pad opening 8a (electrode pad 4). Instead, a dummy wiring layer 17, a dummy electrode 18, and a dummy active area are disposed to ensure the planarity of the chip. This disposition makes it possible to prevent members comprising the circuit from being damaged by pressure applied during probing to the electrode pad 4 or the like and degradation in the characteristics of the semiconductor element. However, the area under the electrode pad 4 must be ensured as an area where a circuit is not disposed in the peripheral region 3. Therefore, when the functions provided in a semiconductor integrated circuit are increased by microminiaturization and the number of required electrode pads is increased, the peripheral region 3 will be further enlarged.

To cope with this, as illustrated in FIG. 4, for example, this embodiment is so structured that the following is implemented: the embodiment includes the planar ring-shaped protecting via 9 that is provided in the interlayer insulating film 6 under the electrode pad 4 and one side of which is coupled with the wiring layer 5 as the uppermost layer comprising the electrode pad 4; the protecting wiring layer 10 that is provided under the electrode pad 4 and is coupled only with the other side of the protecting via 9; and the width x of the protecting via 9 is made equal to or larger than the width y of each circuit via 7. As a result, it is possible to ensure the reliability of the semiconductor device and suppress increase in chip size. A via that does not comprise the circuit may be provided inside the ring of the protecting via 9.

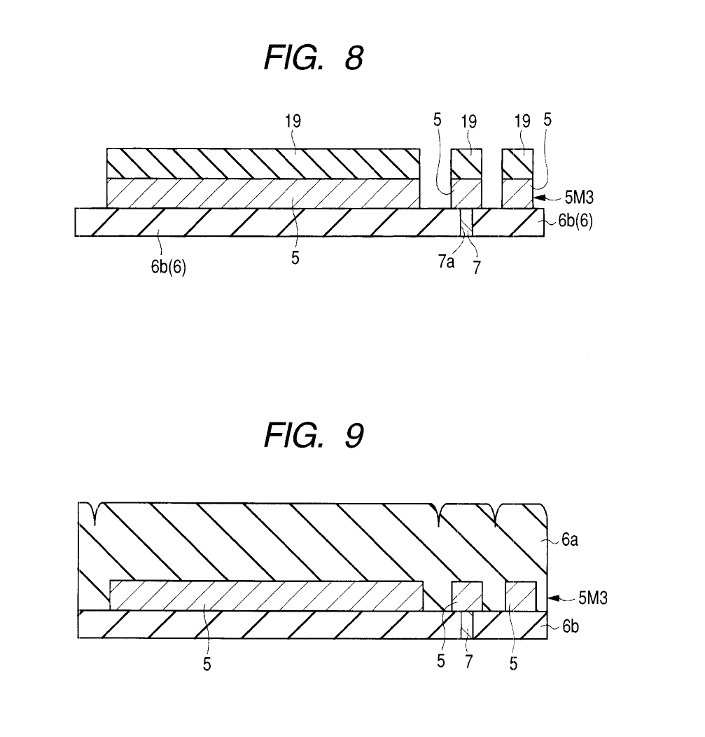

Description will be given to a manufacturing method for the semiconductor device in this embodiment step by step with reference to FIG. 8 to FIG. 19. The MISFETs and multiple wiring layers (multiplayer interconnection) comprising the circuit can be manufactured by publicly known techniques. Therefore, the description thereof will be omitted and description will be given with a focus on the formation of the protecting via 9 and the protecting wiring layer 10.

As illustrated in FIG. 8, a metal film is formed over an interlayer insulating film 6b (interlayer insulating film 6) with a circuit via 7 formed in a hole 7a. Then, a photoresist film 19 patterned by photolithography is formed over the metal film and the metal film is etched using the photoresist film 19 as a mask to form a wiring layer 5. The interlayer insulating film 6b is comprised of a silicon oxide film formed by, for example, CVD (Chemical Vapor Deposition). The metal film is comprised of an aluminum film formed by, for example, sputtering. The formed wiring layer 5 comprises the wiring layer 5M3 as the third layer illustrated in FIG. 2.

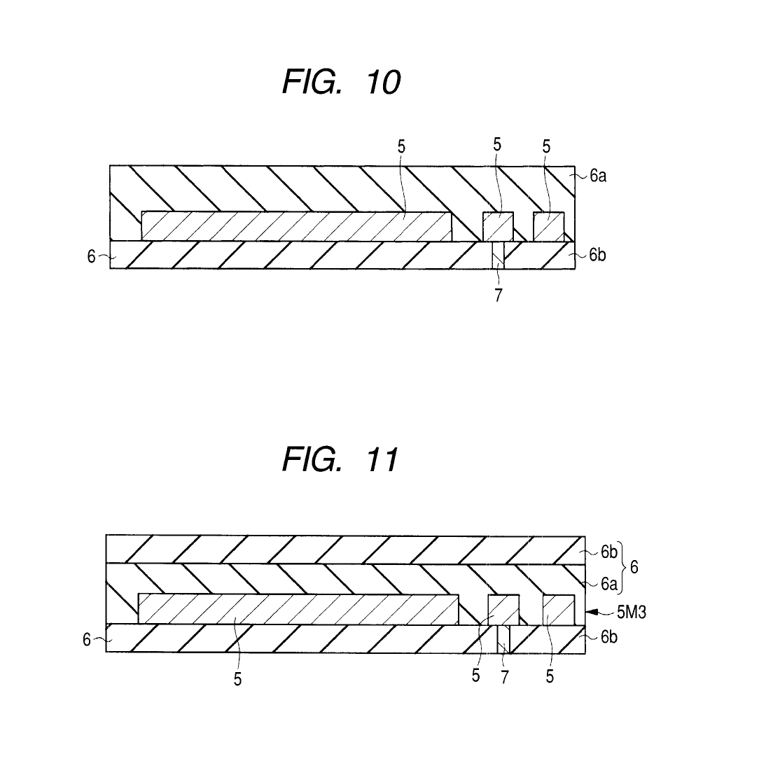

Subsequently, the photoresist film 19 is removed and then an interlayer insulating film 6a is formed so that the gaps in the wiring layer 5M3 as the third layer are filled as illustrated in FIG. 9. Thereafter, the interlayer insulating film 6a is planarized (FIG. 10). The interlayer insulating film 6a may be any insulating film as long as the insulating film is excellent in the property of filling and is comprised of a silicon oxide film formed by, for example, HDP-CVD (High Density Plasma CVD).

Subsequently, an interlayer insulating film 6b is formed over the interlayer insulating film 6a as illustrated in FIG. 11. The interlayer insulating film 6b is comprised of a silicon oxide film formed by, for example, CVD. The interlayer insulating film 6a and the interlayer insulating film 6b comprise an interlayer insulating film 6. The thickness thereof is adjusted so that the wiring layer 5M3 as the third layer and the wiring layer thereabove are electrically isolated from each other.

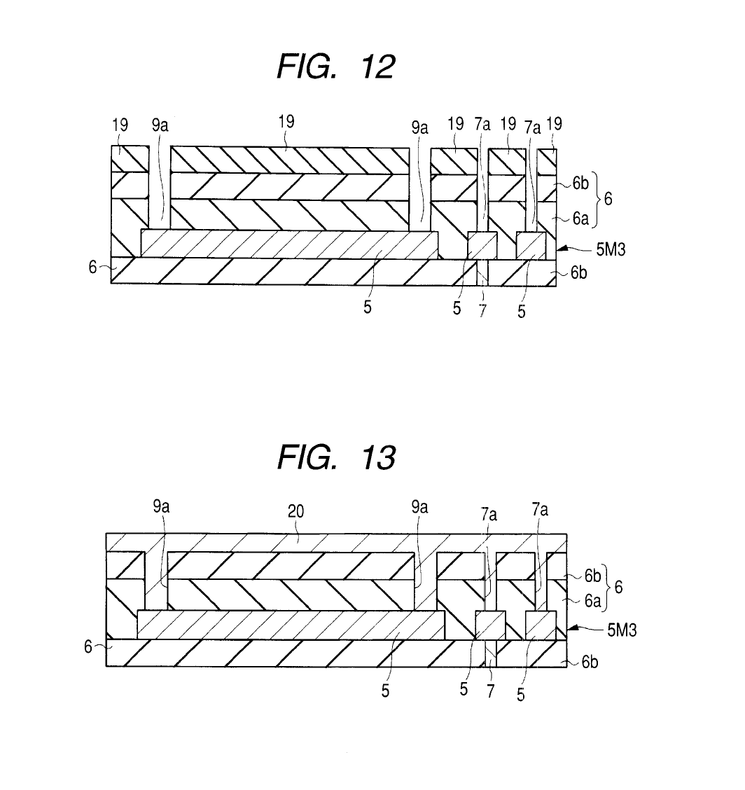

Thereafter, as illustrated in FIG. 12, a photoresist film 19 patterned by photolithography is formed over the interlayer insulating film 6. The interlayer insulating film 6 is etched using the photoresist film 19 as a mask to form holes 7a and a trench 9a in the interlayer insulating film 6. At this time, adjustment is so made that the width of the trench 9a (the right and left direction in the drawing) is equal to or larger than the width of each hole 7a (the right and left direction in the drawing). The trench 9a is so formed that the planar shape thereof is ring shape as illustrated in FIG. 3.

Subsequently, the photoresist film 19 is removed and then barrier metal (not shown) is formed on the side walls of the holes 7a and trench 9a as illustrated in FIG. 13. A metal film 20 is so formed that the holes 7a and the trench 9a are filled therewith with the barrier metal in-between. The metal film 20 is comprised of a tungsten film of, for example, high-melting point metal.

Subsequently, superfluous portions of the metal film 20 and barrier metal are removed by polishing as illustrated in FIG. 14. Circuit vias 7 are thereby formed in the holes 7a and the protecting via 9 is formed in the trench 9a. In this embodiment, the width of the protecting via 9 is made equal to or larger than the width of each circuit via 7 because of the relation between the width of the trench 9a and the width of each hole 7a.

Subsequently, a metal film 5a is formed over the interlayer insulating film 6 in which the circuit vias 7 and protecting via 9 are formed, as illustrated in FIG. 15. This metal film 5a is comprised of an aluminum film formed by, for example, sputtering.

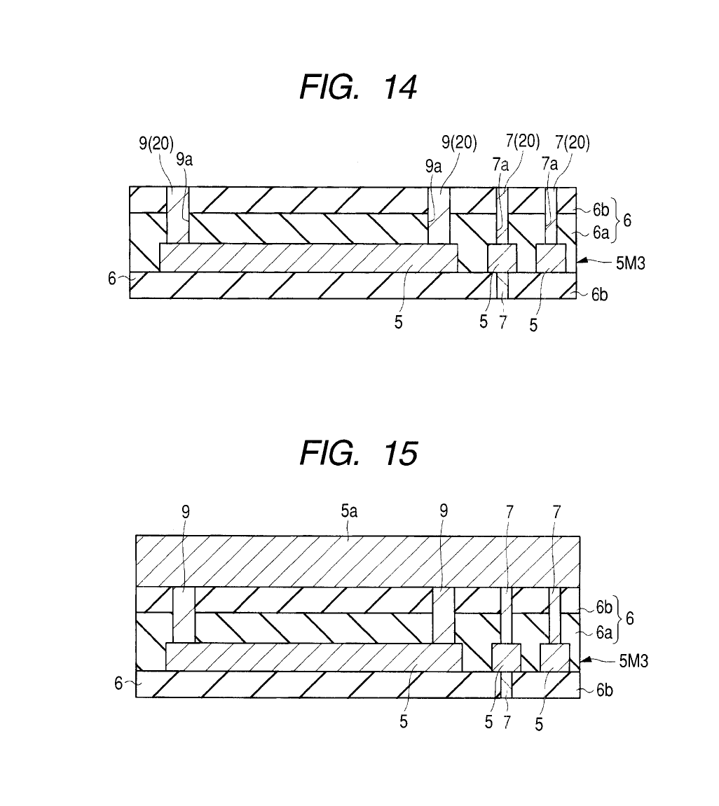

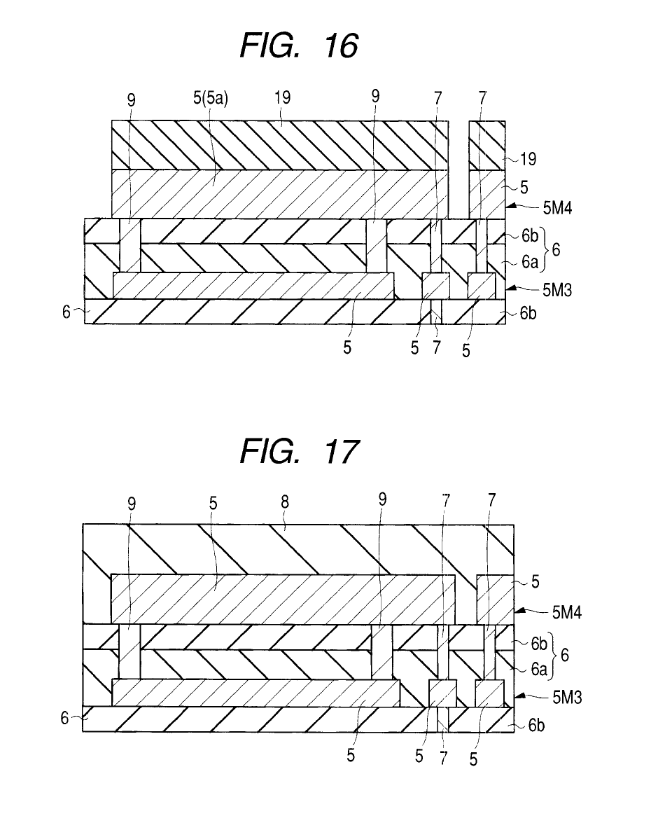

Subsequently, a photoresist film 19 patterned by photolithography is formed over the metal film 5a as illustrated in FIG. 16. The metal film 5a is etched using the photoresist film 19 as a mask to form a wiring layer 5. The formed wiring layer 5 comprises the wiring layer 5M4 as the fourth layer (uppermost layer) illustrated in FIG. 2.

Subsequently, the photoresist film 19 is removed and then a surface protective film 8 is formed so that the gaps in the wiring layer 5M4 as the fourth layer are filled as illustrated in FIG. 17. The surface protective film 8 is comprised of a polyimide film formed by, for example, application. In this embodiment, the surface protective film 8 is of monolayer structure but may be of laminated structure.

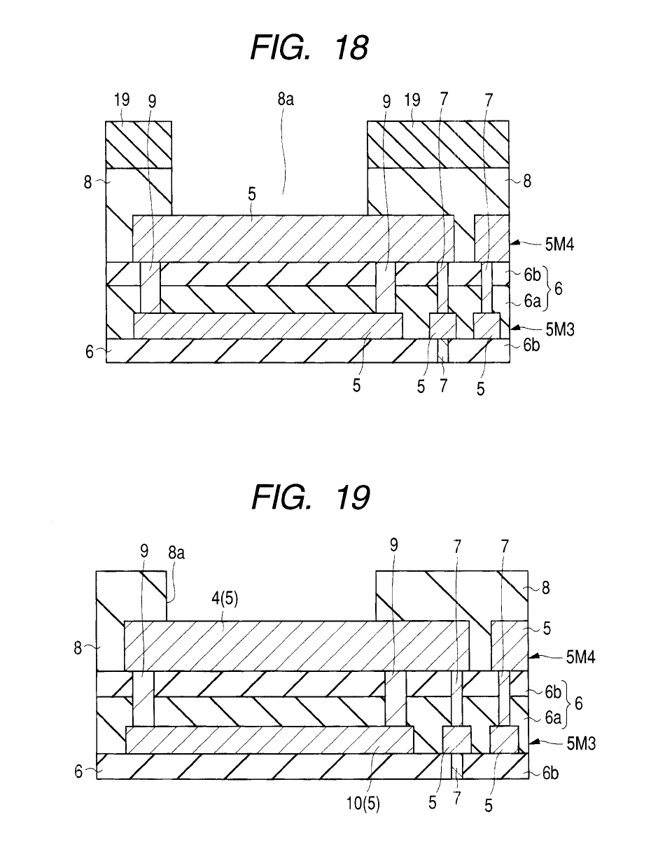

Subsequently, a photoresist film 19 patterned by photolithography is formed over the surface protective film 8 as illustrated in FIG. 18. The surface protective film 8 is etched using the photoresist film 19 as a mask to form a pad opening 8a in the surface protective film 8. Subsequently, the photoresist film 19 is removed to expose part of the wiring layer 5 as the uppermost layer in the pad opening 8a and an electrode pad 4 is thus formed (FIG. 19). As a result, the semiconductor device in this embodiment illustrated in FIG. 1 and FIG. 2 is finished.

### Second Embodiment

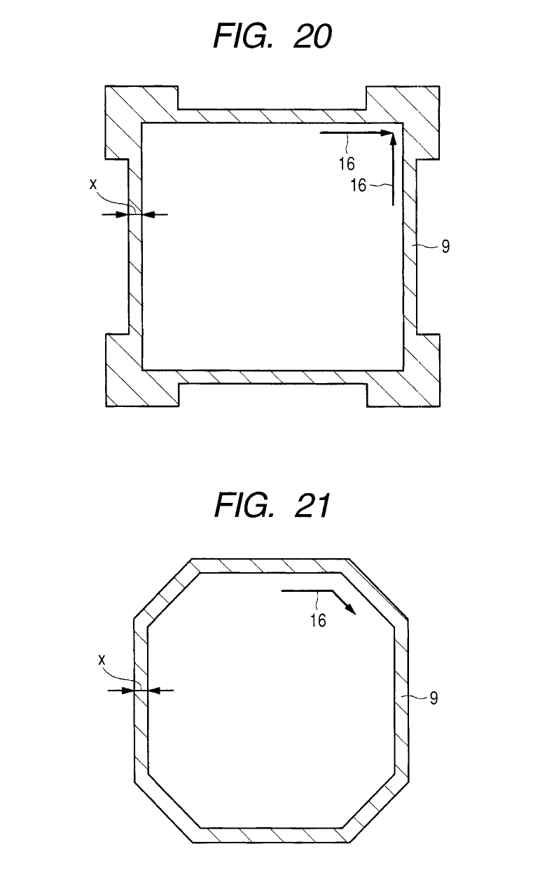

In the description of the first embodiment, the protecting via 9 whose shape on a plane is rectangular as illustrated in FIG. 3 has been taken as an example. In the description of the second embodiment, meanwhile, cases where the planar ring shape of the protecting via 9 is variously modified will be taken as examples. The drawings from FIG. 20 to FIG. 22 are schematic diagrams illustrating a plane of a substantial part of a semiconductor device in this embodiment. The protecting via 9 in this embodiment is so configured that the following is implemented as described with reference to, for example, FIG. 5: a crack 15 is prevented from being caused to progress beyond the planar ring-shaped protecting via 9 or the protecting wiring layer 10 by stress 16 produced when a probe pin 14 is brought into contact with the electrode pad 4. The constituent elements other than the shape of the protecting via 9 are the same as in the first embodiment; therefore, description will be given with a focus on a difference. The semiconductor device in this embodiment can be manufactured by the same process as of the manufacturing method described in relation to the first embodiment.

In the protecting via 9 illustrated in the FIG. 20, the width of the corners of the planar ring shape is increased. When the planar ring shape is simply rectangular, stress 16 is applied to the corners thereof from both side and stress 16 is prone to be concentrated there. To cope with this, the width of the corners is increased to enhance the strength of the protecting via 9. In the protecting via 9 illustrated in FIG. 20, that is, the planar ring shape is rectangular and the width of the corners is larger than the width x of the sides. The width x of each side may be identical with the width y of each circuit via 7. (Refer to FIG. 2.) In FIG. 20, the corners of the protecting via 9 are in L shape. However, the shape of the corners need not be in this shape and any shape is acceptable as long as the width of the corners is larger than the width x of the sides.

In the protecting via 9 illustrated in FIG. 21, the angle of each corner of the planar ring shape is made gentler. When the planar ring shape is simply rectangular, stress 16 is applied to the corners with an angle of 90° from both sides and stress 16 is prone to be concentrated there. To cope with this, the angle of each corner is made gentler to make stress 16 less prone to be concentrated. The width x of each side may be identical with the width y of each circuit via 7. (Refer to FIG. 2.) In FIG. 21, the planar ring shape of the protecting via 9 is of octagon having eight corners and the angle of each corner is obtuse and 90° or larger. However, the shape of the protecting via need not be this shape and any shape is acceptable as long as the angle of each corner is made gentler. Further, the planar ring shape of the protecting via 9 may be circular or oval and have no angle.

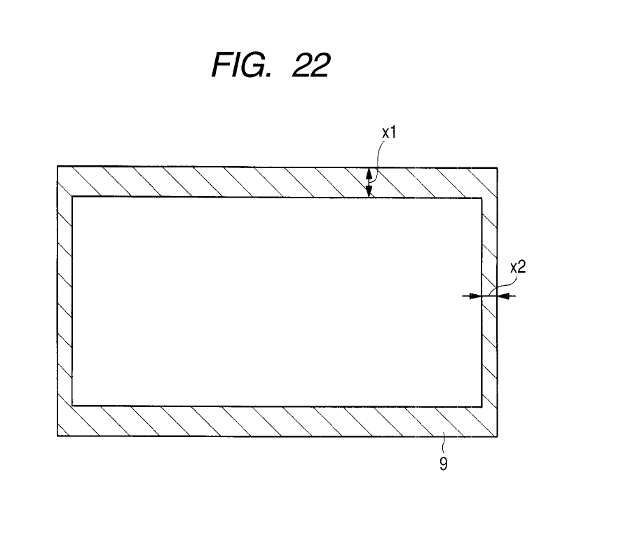

In the protecting via 9 illustrated in FIG. 22, the planar ring shape is rectangular and the width x1 of each long side is larger than the width x2 of each short side. When the planar ring shape is simply rectangular, the long sides are inferior in strength to the short sides. To cope with this, the width x1 of each long side is made larger than the width x2 of each short side to enhance stress tolerance. The width x2 of each short side may be identical with the width y of each circuit via 7. (Refer to FIG. 2.)

### Third Embodiment

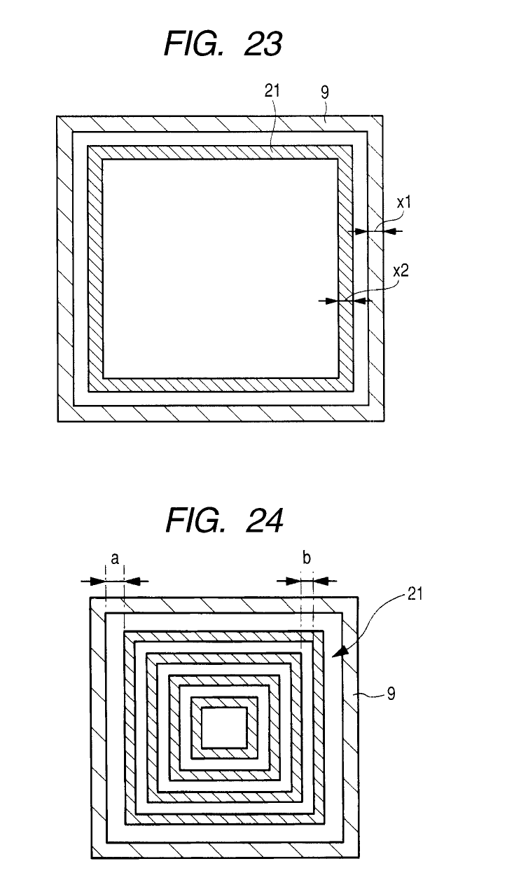

In the description of the first embodiment, a case where one protecting via 9 whose ring shape is rectangular on a plane as illustrated in FIG. 3 has been taken as an example. In the description of the third embodiment, meanwhile, a case where another via (hereafter, referred to as inner via) is provided inside the ring of the protecting via 9 will be taken as an example. FIG. 23 is a schematic diagram of a plane of a substantial part of a semiconductor device in this embodiment. The protecting via 9 and inner via 21 in this embodiment prevent the following from taking place: a crack 15 is caused to progress beyond the ring by stress 16 produced when a probe pin 14 is brought into contact with the electrode pad 4 over the planar ring-shaped protecting via 9 as illustrated in FIG. 5, for example. The constituent elements other than the provision of the inner via 21 are the same as in the first embodiment; therefore, description will be given with a focus on a difference. The inner via 21 is formed similarly with the protecting via 9. The semiconductor device in this embodiment can be manufactured by the same process as of the manufacturing method described in relation to the first embodiment.

As illustrated in FIG. 23, an inner via geometrically similar to the planar ring-shaped protecting via 9, that is, a planar ring-shaped inner via 21 is provided inside the planar ring-shaped protecting via. Inside the planar ring-shaped protecting via 9, specifically, there is provided the planar ring-shaped inner via 21 whose width (width x2) is smaller than the width x1 of the protecting via 9. By doubling the ring and making the ring on the outer radius side (protecting via 9) thicker than the ring on the inner radius side (inner via 21), the following can be implemented: when a crack 15 is produced by stress 16 that cannot be blocked by the ring on the inner radius side, the crack 15 can be stopped on the outer radius side. This is because energy is absorbed by destroying the ring on the inner radius side. Disposing the planar ring-shaped inner via 21 whose width (width x2) is smaller than the width x1 of the protecting via 9 as mentioned above implements the following: the effect of stopping a crack 15 by the outer protecting via 9 is enhanced as compared with cases where double rings of the same width are disposed. The width x2 of the inner via 21 may be identical with the width y of each circuit via 7. (Refer to FIG. 2.)

### Fourth Embodiment

In the description of this embodiment, a case where a via (hereafter, referred to as inner via) is provided inside the ring of the planar ring-shaped protecting via 9 described in relation to the first embodiment. (For the planar ring-shaped protecting via, refer to FIG. 3, for example.) The drawings from FIG. 24 to FIG. 31 are schematic diagrams illustrating a plane of a substantial part of a semiconductor device in this embodiment. The protecting via 9 and inner via 21 in this embodiment prevent the following from taking place: a crack 15 is caused to progress beyond the protecting via 9 by stress 16 produced when a probe pin 14 is brought into contact with the electrode pad 4 over the planar ring-shaped protecting via 9 as illustrated in FIG. 5, for example. The constituent elements other than the provision of the inner via 21 are the same as in the first embodiment; therefore, description will be given with a focus on a difference. The inner via 21 is formed similarly with the protecting via 9. The semiconductor device in this embodiment can be manufactured by the same process as of the manufacturing method described in relation to the first embodiment.

In this embodiment, the inner via 21 is provided inside the planar ring-shaped protecting via 9 as illustrated in FIG. 24 to FIG. 31. The distance a between the protecting via 9 and the inner vias 21 is larger than the distance b between inner vias 21. As a result, a crack 15 is prone to be produced between inner vias 21 and a crack 15 is less prone to be produced between the protecting via 9 and the inner vias 21. Therefore, a crack 15 can be prevented from progressing beyond the protecting via 9. Hereafter, description will be given to the multiple inner vias 21 illustrated in FIG. 24 to FIG. 31.

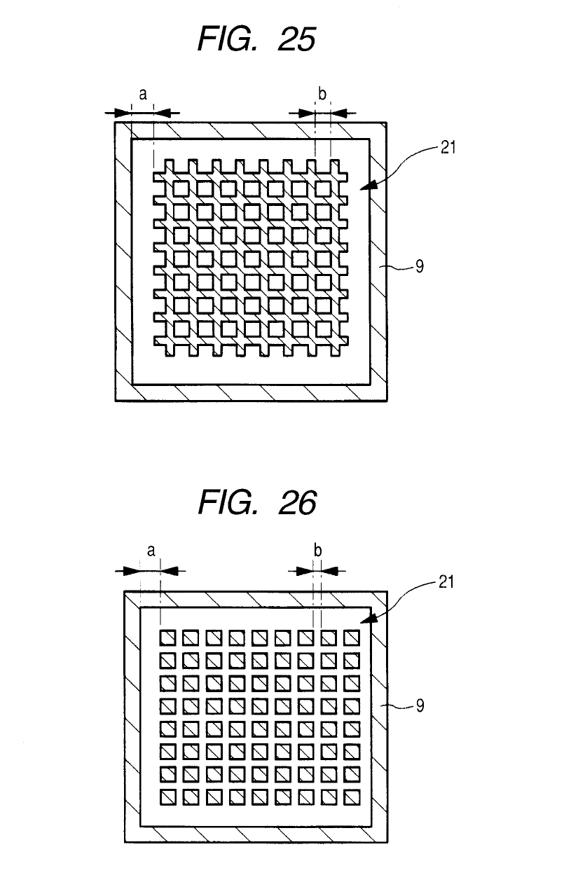

The multiple inner vias 21 illustrated in FIG. 24 are in multiple ring shape on a plane. The inner vias 21 illustrated in FIG. 25 are in a mesh pattern on a plane. The multiple inner vias 21 illustrated in FIG. 26 are in a dot matrix pattern on a plane. By providing these inner vias 21 inside the protecting via 9, a crack 15 can be prevented from progressing beyond the protecting via 9.

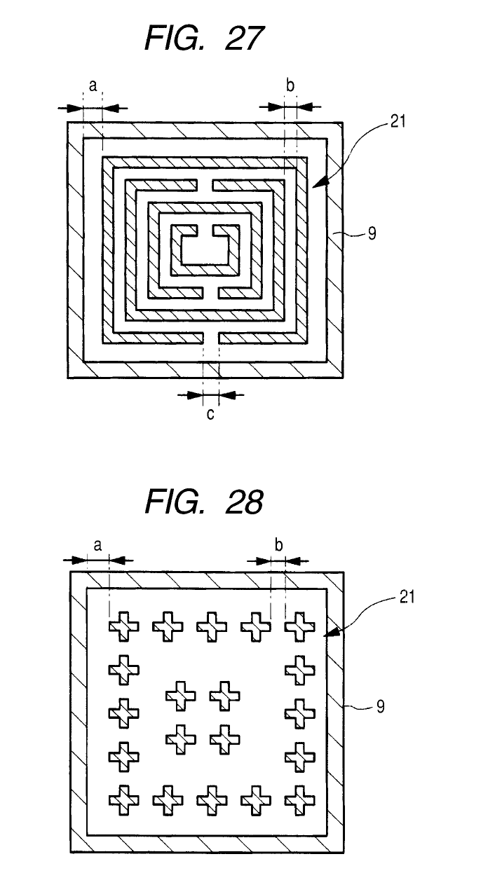

The multiple inner vias 21 illustrated in FIG. 27 are in multiple ring shape on a plane and some of them are provided with a cut. The length c of each of these cuts forms a portion that is lower in stress tolerance and a portion where stress 16 is likely to escape can be identified. The cuts are so positioned that the cuts do not adjoin to each other in adjoining inner vias 21. To prevent stress from reaching the protecting via 9, the following measure is taken: the distance a between the protecting via 9 and the multiple inner vias 21 is made larger than the distance b between vias 21; and at the same time, the distance a between the protecting via 9 and the multiple inner vias 21 is made larger than the length c of each cut. As a result, a crack 15 is most prone to be produced at a cut and a crack 15 is secondly most prone to be produced between inner vias 21. Therefore, a crack 15 can be prevented from progressing beyond the protecting via 9.

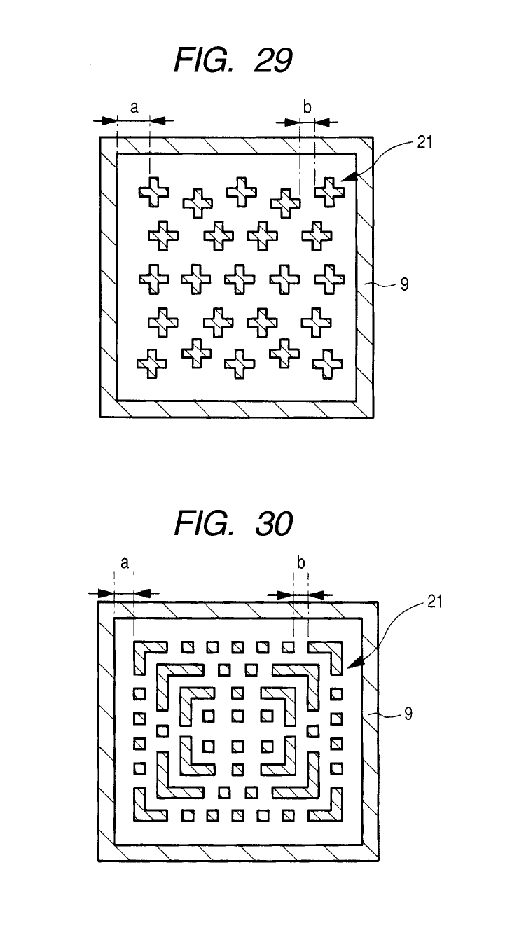

The multiple inner vias 21 illustrated in FIG. 28 and FIG. 29 are each in cross shape on a plane and evenly disposed. At least with respect to spacing b, a sufficient distance is ensured to prevent inner vias 21 from being brought into contact with each other. As a result, a portion low in stress tolerance is formed and a portion where stress 16 is prone to escape can be identified. Provision of the multiple inner vias 21 inside the protecting via 9 as mentioned above makes it possible to prevent a crack 15 from progressing beyond the protecting via 9.

The multiple inner vias 21 illustrated in FIG. 30 are in multiple ring shape on a plane and parts of the rings are formed in dot shape. Inner vias 21 are prevented from being brought into contact with each other and, at least with respect to spacing b, a sufficient distance is ensured. The areas of spacing b are so positioned that the areas of spacing b do not adjoin to each other in adjoining inner vias 21. As a result, a portion that is lower in stress tolerance is formed and a portion where stress 16 is prone to escape can be identified. When the planar ring shape of each of the multiple inner vias 21 is rectangular as illustrated in FIG. 30, it is desirable that the corners should not be in dot shape for the enhancement of stress tolerance and dot-shaped portions should be positioned at sides.

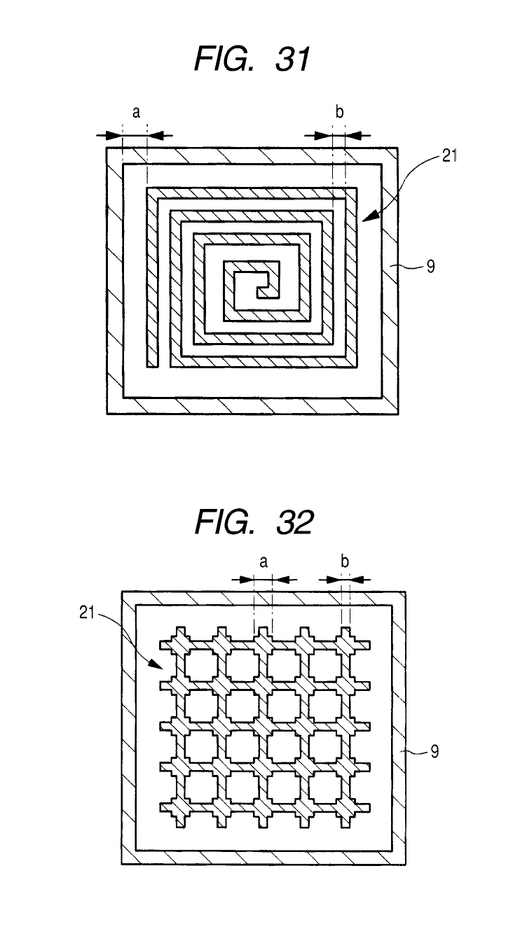

The inner via 21 illustrated in FIG. 31 is in spiral shape on a plane. By providing the spiral inner via 21 with spacing b ensured inside the protecting via 9, a crack 15 can be prevented from progressing beyond the protecting via 9.

### Fifth Embodiment

In the description of this embodiment, a case where a via (hereafter, referred to as inner via) is provided inside the ring of the planar ring-shaped protecting via 9 described in relation to the first embodiment will be taken as an example. (For the planar ring-shaped protecting via, refer to FIG. 3, for example.) The drawings from FIG. 32 to FIG. 34 are schematic diagrams illustrating a plane of a substantial part of a semiconductor device in this embodiment. The protecting via 9 and inner via 21 in this embodiment prevent the following from taking place: a crack 15 is caused to progress beyond the protecting via 9 by stress 16 produced when a probe pin 14 is brought into contact with the electrode pad 4 over the planar ring-shaped protecting via 9 as illustrated in FIG. 5, for example. The constituent elements other than the provision of the inner via 21 are the same as in the first embodiment; therefore, description will be given with a focus on a difference. The inner via 21 is formed similarly with the protecting via 9. The semiconductor device in this embodiment can be manufactured by the same process as of the manufacturing method described in relation to the first embodiment.

In this embodiment, the inner via 21 having different widths, width a and width b, is provided inside the planar ring-shaped protecting via 9 as illustrated in FIG. 32 to FIG. 34. The width a is larger than the width b and the width b is identical with the width y of each circuit via 7. (Refer to FIG. 2.) As a result, it is possible to make a crack 15 prone to be produced in proximity to a portion of width b of the inner via 21 to prevent a crack 15 from progressing beyond the protecting via 9.

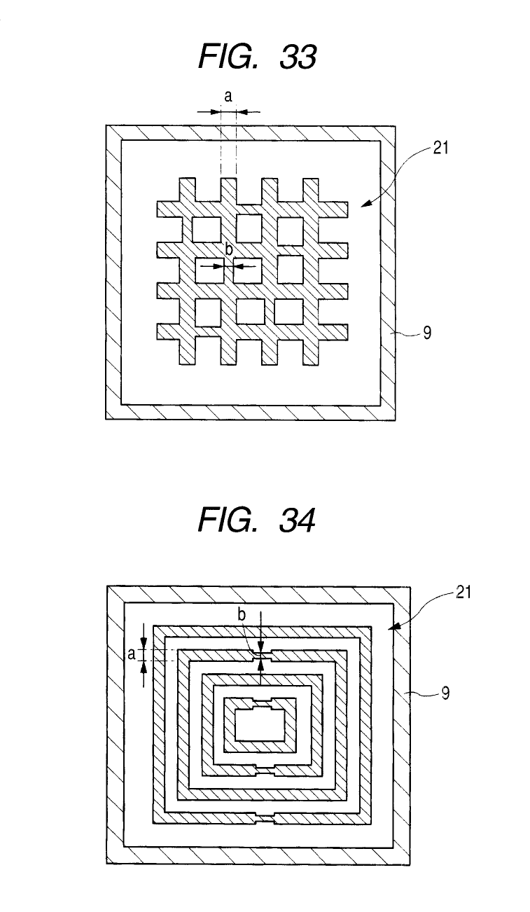

The inner vias 21 illustrated in FIG. 32 and FIG. 33 are in a mesh pattern on a plane. The width b of portions of the inner via 21 other than points of intersection in the mesh is made equal to the width y of each circuit via 7 and smaller than the width a of each portion of the inner via 21 that forms a point of intersection. The inner vias 21 illustrated in FIG. 34 are in multiple ring shape on a plane. The width b of each of parts thereof is made equal to the width y of each circuit via 7 and smaller than the width a of each of the other portions of the inners vias 21.

By providing a narrow portion in the inner vias 21, a crack 15 is made prone to be produced there. As a result, it is possible to prevent a crack 15 from progressing beyond the protecting via 9.

### Sixth Embodiment

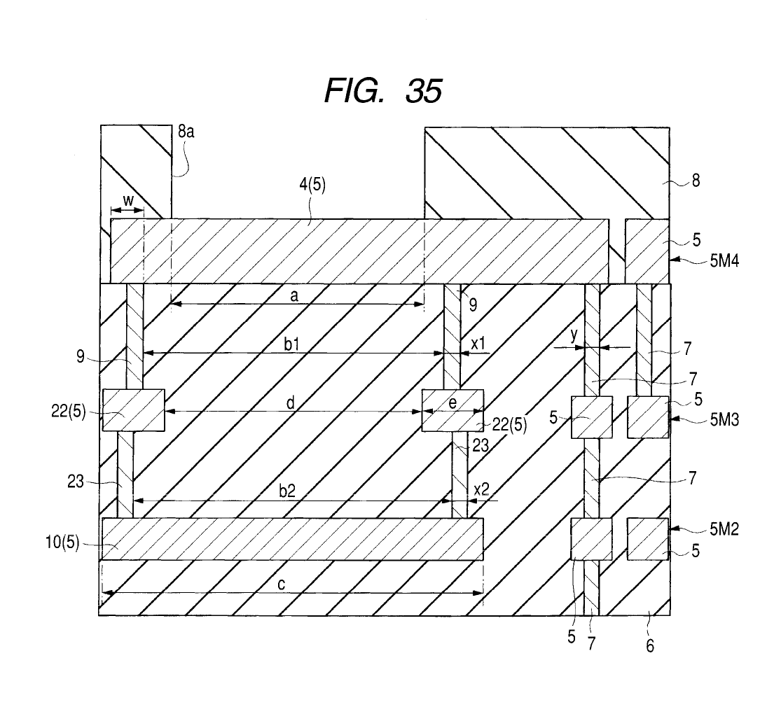

FIG. 35 is a schematic diagram illustrating a section of a substantial part of a semiconductor device in this embodiment. In the description of the first embodiment, a case where the following is implemented as illustrated in FIG. 2, for example, has been taken as an example: the electrode pad 4 is provided in part of the wiring layer 5M4 as the uppermost layer of the four wiring layers 5; the protecting wiring layer 10 is provided in part of the wiring layer 5M3 as the third layer thereunder; and the protecting via 9 is provided between the electrode pad 4 and the protecting wiring layer 10. The sixth embodiment is different from the first embodiment only in the points illustrated in FIG. 35. That is, the protecting wiring layer 10 is not provided in the wiring layer 5M3 but is provided in the wiring layer 5M2 as the second layer thereunder. Further, two protecting vias 9 and 23 and an intermediate layer that couples them together are provided between the electrode pad 4 and the protecting wiring layer 10.

Therefore, the semiconductor device in this embodiment includes the following over the semiconductor substrate 1S: multiple wiring layers 5 respectively provided through the interlayer insulating film 6; circuit vias 7 that are provided in the interlayer insulating film 6 between upper and lower wiring layers 5 of the multiple wiring layers 5 and couple the upper and lower wiring layers 5 together; and a surface protective film 8 provided over the wiring layers 5. In part of the uppermost layer of the wiring layers 5, there is provided an electrode pad 4 exposed in a pad opening 8a provided in the surface protective film 8. In the interlayer insulating film 6 under the electrode pad 4, there is provided the planar ring-shaped protecting via 9 one side of which is coupled with the wiring layer 5 comprising the electrode pad 4. Of the multiple wiring layers 5, one positioned under the electrode pad 4 is provided with the planar ring-shaped intermediate layer 22 coupled with the other side of the protecting via 9. The interlayer insulating film 6 positioned under the intermediate layer 22 is provided with the planar ring-shaped protecting via 23 one side of which is coupled with the intermediate layer 22. Of the multiple wiring layers 5, one positioned under the intermediate layer 22 is provided with a protecting wiring layer 10 coupled only with the other side of the protecting via 23. The width x1 of the protecting via 9 and the width x2 of the protecting via 23 are made equal to or larger than the width y of each circuit via 7. Over the principal surface of the semiconductor substrate 1S positioned under the protecting wiring layer 10, there is provided the same MISFET 12 as in FIG. 2 referred to in relation to the above embodiments.

The progress of cracking can be prevented as described below in the interlayer insulating film (insulating film) 6 under the electrode pad 4: the progress of a crack 15 in the horizontal direction (the right and left direction in FIG. 35) can be prevented by the protecting vias 9, 23 comprised of a tungsten film (metal film); and the progress of a crack 15 in the downward direction (the downward direction in FIG. 35) can be prevented by the protecting wiring layer 10 comprised of an aluminum film (metal film). It can be thought that this is because the protecting via 9 and the protecting wiring layer 10 function as cushioning materials and a crack 15 progresses along the boundary between the metal films and the insulating film. While the protecting wiring layer 10 is provided in the wiring layer 5M3 as the third layer in the first embodiment, the protecting wiring layer 10 is provided in the wiring layer 5M2 as the second layer in this embodiment. As a result, the distance from the electrode pad 4 to the protecting wiring layer 10 is lengthened and the progress of a crack 15 beyond the protecting wiring layer 10 can be more reliably prevented. In the description of this embodiment, a case where the protecting wiring layer 10 is provided in the second wiring layer 5M2 is taken as an example. However, the protecting wiring layer 10 need not be provided unless a crack 15 progresses to the second wiring layer 5M2.

With respect to the distances (widths) in the right and left direction in FIG. 35, the following assumption will be made: the size of the pad opening 8a is a; the inside size of the first protecting via 9 is b1; the inside size of the second protecting via 23 is b2; the outside size of the protecting wiring layer 10 is c; the inside size of the intermediate layer 22 is d; and the distance from an end of the uppermost wiring layer 5 comprising the electrode pad 4 to an inside end of the planar ring-shaped protecting via 9 is w. Further, the width of the first protecting via 9 is x1; the width of the second protecting via 23 is x2; the width of each circuit via 7 is y; and the width of the intermediate layer 22 is e.

To further enhance stress tolerance, the semiconductor device only has to be configured so that the following relation holds: a≦b1, a≦b2, a≦d, d≦b1, d≦b2, b1≦b2, b2≦c, x1≦y, x2≦y, and w>0. With this configuration, a section comprised of the electrode pad 4, protecting vias 9, 23, intermediate layer 22, and protecting wiring layer 10 is not rectangular unlike a section of the semiconductor device in the first embodiment. The section in the first embodiment is comprised of the electrode pad 4, protecting via 9, and protecting wiring layer 10. (Refer to FIG. 2, for example.) With the above configuration, a section comprised of the electrode pad 4, protecting vias 9, 23, intermediate layer 22, and protecting wiring layer 10 is trapezoidal as illustrated in FIG. 35. For this reason, the distance from the electrode pad 4 to the protecting wiring layer 10 is lengthened and the progress of a crack 15 beyond the protecting wiring layer 10 can be more reliably prevented. Further, the distance from the electrode pad 4 to the protecting via 23 is lengthened and the progress of a crack 15 beyond the protecting via 23 can be more reliably prevented.

To enhance the degree of freedom in providing a wiring layer 5 comprising the circuit under the protecting wiring layer 10, the semiconductor device only has to be configured so that the following relation holds: a≦b1, d≦b1, d≧b2, b1≧b2, b2≦c, x1≦y, and x2≦y. With this configuration, the section comprised of the electrode pad 4, protecting vias 9, 23, intermediate layer 22, and protecting wiring layer 10, illustrated in FIG. 35, is inverted trapezoidal. For this reason, the distance from the electrode pad 4 to the protecting wiring layer 10 is lengthened and the progress of a crack 15 beyond the protecting wiring layer 10 can be more reliably prevented. Further, the area encircled with the electrode pad, protecting vias 9, 23, and intermediate layer 22 is narrowed and the degree of freedom in providing a wiring layer 5 comprising the circuit under the protecting wiring layer 10 can be enhanced.

The semiconductor device in this embodiment can be manufactured by the same process as of the manufacturing method described in relation to the first embodiment. As described in relation to the third to fifth embodiments, a via may be provided inside the planar ring-shaped protecting vias 9, 23.

### Seventh Embodiment

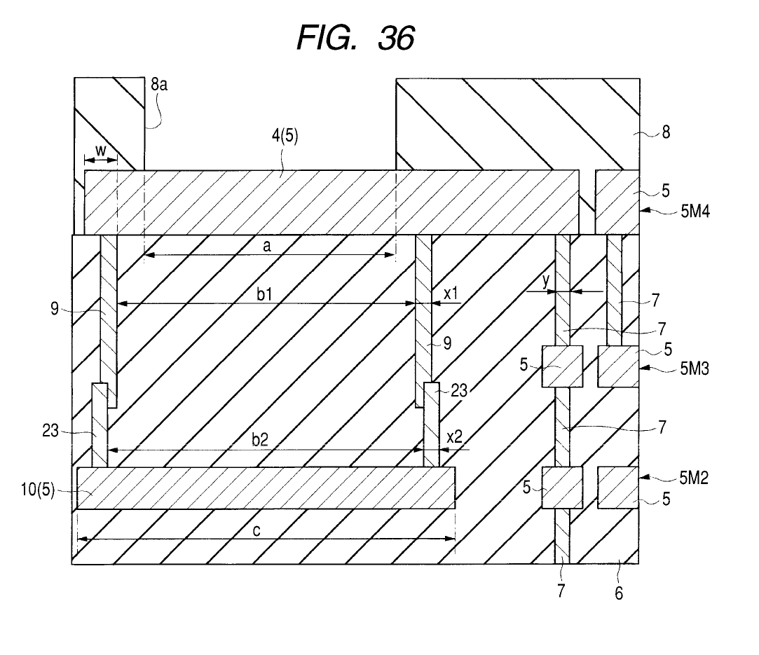

FIG. 36 is a schematic diagram illustrating a section of a substantial part of a semiconductor device in this embodiment. In the description of the first embodiment, a case where the following is implemented as illustrated in FIG. 2, for example, has been taken as an example: the electrode pad 4 is provided in part of the fourth wiring layer 5M4 as the uppermost layer of the four wiring layers 5; the protecting wiring layer 10 is provided in part of the wiring layer 5M3 as the third layer thereunder; and the protecting via 9 is provided between the electrode pad 4 and the protecting wiring layer 10. The seventh embodiment is different from the first embodiment only in the points illustrated in FIG. 36. That is, the protecting wiring layer 10 is not provided in the wiring layer 5M3 as the third embodiment but is provided in the wiring layer 5M2 as the second layer thereunder. Further, two protecting vias 9 and 23 are provided between the electrode pad 4 and the protecting wiring layer 10.

Therefore, the semiconductor device in this embodiment includes the following over the semiconductor substrate 1S: multiple wiring layers 5 respectively provided through the interlayer insulating film 6; circuit vias 7 that are provided in the interlayer insulating film 6 between upper and lower wiring layers 5 of the multiple wiring layers 5 and couple the upper and lower wiring layers 5 together; and a surface protective film 8 provided over the wiring layers 5. In part of the uppermost layer of the wiring layers 5, there is provided an electrode pad 4 exposed in a pad opening 8a provided in the surface protective film 8. In the interlayer insulating film 6 under the electrode pad 4, there is provided the planar ring-shaped protecting via 9 one side of which is coupled with the wiring layer 5 comprising the electrode pad 4. The interlayer insulating film 6 under the protecting via 9 is provided with the planar ring-shaped protecting via 23 one end of which coupled with the other side of the protecting via 9. Of the multiple wiring layers 5, one positioned under the electrode pad 4 is provided with the protecting wiring layer 10 coupled only with the other side of the protecting via 23. Over the principal surface of the semiconductor substrate 1S positioned under the protecting wiring layer 10, there is provided MISFET 12. The width x1 of the protecting via 9 and the width x2 of the protecting via 23 are made equal to or larger than the width y of each circuit via 7.

The progress of cracking can be prevented as described below in the interlayer insulating film 6 (insulating film) under the electrode pad 4: the progress of a crack 15 in the horizontal direction (the right and left direction in FIG. 36) can be prevented by the protecting vias 9, 23 comprised of a tungsten film (metal film); and the progress of a crack 15 in the downward direction (the downward direction in FIG. 36) can be prevented by the protecting wiring layer 10 comprised of an aluminum film (metal film). It can be thought that this is because the protecting via 9 and the protecting wiring layer 10 function as cushioning materials and a crack 15 progresses along the boundary between the metal films and the insulating film. While the protecting wiring layer 10 is provided in the wiring layer 5M3 as the third layer in the first embodiment, the protecting wiring layer 10 is provided in the wiring layer 5M2 as the second layer in this embodiment. As a result, the distance from the electrode pad 4 to the protecting wiring layer 10 is lengthened and the progress of a crack 15 beyond the protecting wiring layer 10 can be more reliably prevented. In the description of this embodiment, a case where the protecting wiring layer 10 is provided in the second wiring layer 5M2 is taken as an example. However, the protecting wiring layer 10 need not be provided unless a crack 15 progresses to the second wiring layer 5M2.

In this embodiment, the protecting wiring layer 10 is formed in the wiring layer 5M2 as the second layer, or the second lower layer from the fourth wiring layer 5M4 as the uppermost layer. The protecting via 9 is provided so that it is extended from the interlayer insulating film 6 under the electrode pad 4 to the interlayer insulating film 6 between the wiring layer 5M3 as the third layer, or the layer immediately below the fourth wiring layer 5M4 as the uppermost layer and the protecting wiring layer 10. As a result, part of the protecting via 9 and part of the protecting via 23 overlap with each other and are coupled together.

With respect to the distances (widths) in the right and left direction in FIG. 36, the following assumption will be made: the size of the pad opening 8a is a; the inside size of the first protecting via 9 is b1; the inside size of the second protecting via 23 is b2; the outside size of the protecting wiring layer 10 is c; and the distance from an end of the uppermost wiring layer 5 comprising the electrode pad 4 to an inside end of the planar ring-shaped protecting via 9 is w. Further, the width of the first protecting via 9 is x1; the width of the second protecting via 23 is x2; and the width of each circuit via 7 is y.

To further enhance stress tolerance, the semiconductor device only has to be configured so that the following relation holds: a≦b1, a≦b2, b1≦b2, b2≦c, b2≦(b1+x1+x1)≦(b2+x2+x2), and w>0. With this configuration, a section comprised of the electrode pad 4, protecting vias 9, 23, and protecting wiring layer 10 is not rectangular unlike a section of the semiconductor device in the first embodiment. The section in the first embodiment is comprised of the electrode pad 4, protecting via 9, and protecting wiring layer 10. (Refer to FIG. 2, for example.) With the above configuration, a section comprised of the electrode pad 4, protecting vias 9, 23, and protecting wiring layer 10 is trapezoidal as illustrated in FIG. 36. For this reason, the distance from the electrode pad 4 to the protecting wiring layer 10 is lengthened and the progress of a crack 15 beyond the protecting wiring layer 10 can be more reliably prevented. Further, the distance from the electrode pad 4 to the protecting via 23 is lengthened and the progress of a crack 15 beyond the protecting via 23 can be more reliably prevented.

The semiconductor device in this embodiment can be manufactured by the same process as of the manufacturing method described in relation to the first embodiment. In this embodiment, the first protecting via 9 and the second protecting via 23 are directly coupled together. Therefore, in the step of forming a trench for the first protecting via 9, it is required to increase the amount of etching at least by an amount equivalent to the thickness of the third wiring layer 5M3. As described in relation to the third to fifth embodiments, a via may be provided inside the planar ring-shaped protecting vias 9, 23.

### Eighth Embodiment

As described with reference to FIG. 5, for example, the first embodiment is so configured as to prevent a crack 15 from progressing beyond the planar ring-shaped protecting via 9 or the protecting wiring layer 10 with the following taken into account: when a probe pin 14 is brought into contact with the electrode pad 4, a crack 15 is produced in the interlayer insulating film 6 under the electrode pad 4. This embodiment is so configured as to prevent a crack 15 from being produced in the interlayer insulating film 6 under the electrode pad to prevent a crack 15 from progressing beyond the protecting via 9 or the protecting wiring layer 10. Hereafter, description will be given with a focus on a difference from the first embodiment.

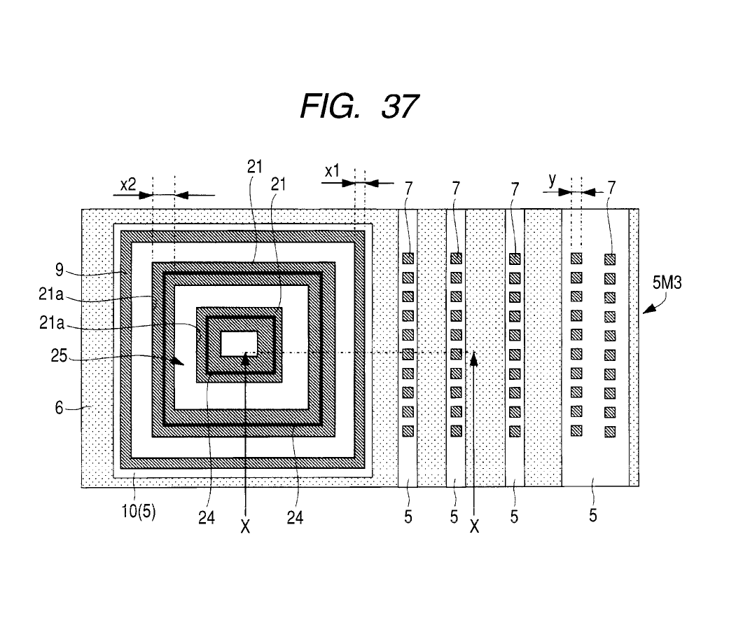

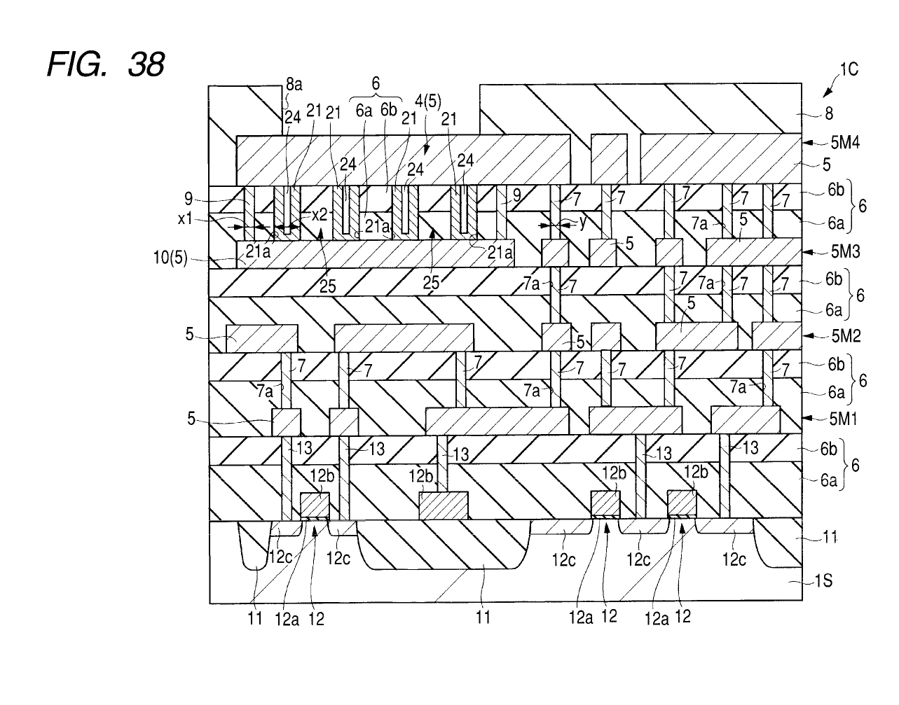

FIG. 37 is a schematic diagram illustrating a plane of a substantial part of a semiconductor device in this embodiment and FIG. 38 is a schematic diagram illustrating the section taken along line X-X of FIG. 37. FIG. 37 is so depicted that the dispositional relation between the protecting via 9 provided over the protecting wiring layer 10 comprised of part of the third wiring layer 5M3 and inner vias 21 having an air gap 24 is clarified. Some members are omitted in the drawing.

As is apparent from comparison between the semiconductor device in the first embodiment illustrated in FIG. 2 and FIG. 3 and the semiconductor device in this embodiment illustrated in FIG. 37 and FIG. 38, this embodiment is different in the following point: the inner vias 21 having an air gap 24 are provided inside the ring of the planar ring-shaped protecting via 9.

Therefore, the semiconductor device in this embodiment includes the following over the semiconductor substrate 1S: multiple wiring layers 5 respectively provided through the interlayer insulating film 6; circuit vias 7 that are provided in the interlayer insulating film 6 between upper and lower wiring layers 5 of the multiple wiring layers 5 and couple the upper and lower wiring layers 5 together; and a surface protective film 8 provided over the wiring layers 5. In part of the uppermost layer of the wiring layers 5, there is provided an electrode pad 4 exposed in a pad opening 8a provided in the surface protective film 8. In the interlayer insulating film 6 under the electrode pad 4, there is provided the planar ring-shaped protecting via 9 one side of which is coupled with the wiring layer 5 comprising the electrode pad 4. Of the multiple wiring layers 5, one positioned under the electrode pad 4 is provided with the protecting wiring layer 10 coupled only with the other side of the protecting via 9. Over the principal surface of the semiconductor substrate 1S positioned under the protecting wiring layer 10, there is provided MISFET 12. The area of the interlayer insulating film 6 encircled with the planar ring-shaped protecting via 9 is provided with the planar ring-shaped inner vias 21 having an air gap 24 formed in a trench 21a. The width x2 of each inner via 21 (trench 21a) is larger than the width x1 of the protecting via 9 (trench 9a) and the width y of each circuit via 7 (hole 7a). Therefore, the trench 9a and the holes 7a are filled with a metal film but the trenches 21a are not filled and an air gap 24 is provided there. The width x1 of the protecting via 9 (trench 9a) may be identical with the width y of each circuit via 7 (hole 7a).

The inner vias 21 formed in the trenches 21a as mentioned above are provided therein with the air gaps 24. These air gaps 24 are capable of absorbing shock as air cushions, for example, when a probe pin is brought into contact with the electrode pad 4. The portions of the interlayer insulating film 6 between the inner vias 21 having the doubly provided air gaps 24, that is, the buffer region 25 between an air gap 24 and an air gap 24 is reduced in sectional area and is reduced in load resistance. For this reason, when stress is too great for the air gaps 24 to resist as air cushions, the stress can be absorbed by letting cracking (destruction) occur in the buffer region 25.

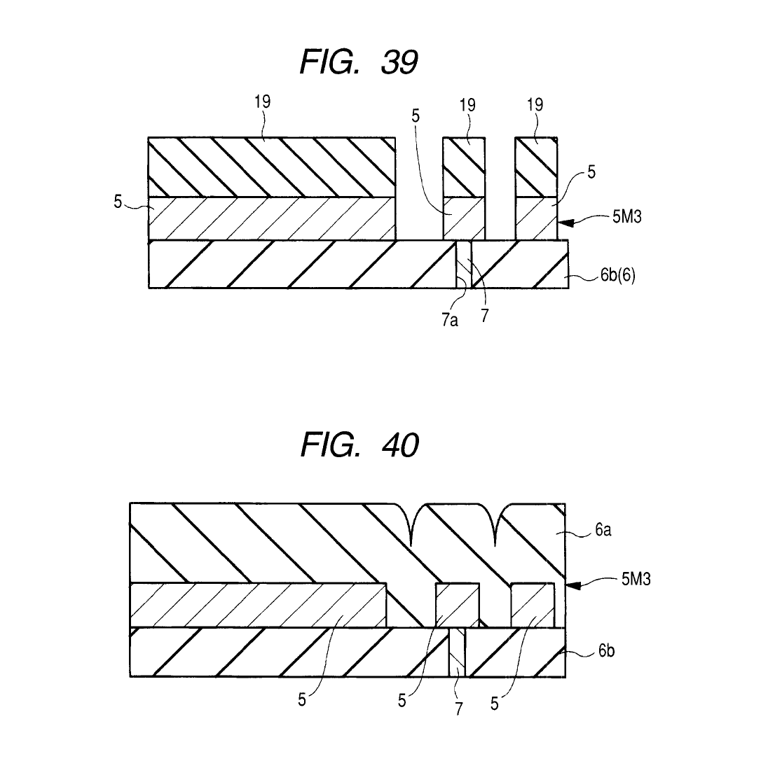

Description will be given to a manufacturing method for the semiconductor device in this embodiment step by step with reference to FIG. 39 to FIG. 47. The MISFETs and multiple wiring layers (multiplayer interconnection) comprising the circuit can be manufactured by publicly known techniques. Therefore, the description thereof will be omitted and description will be given with a focus on the formation of the inner vias 21 having the air gaps 24.

As illustrated in FIG. 39, a metal film is formed over an interlayer insulating film 6b (interlayer insulating film 6) with a circuit via 7 formed in a hole 7a. Then, a photoresist film 19 patterned by photolithography is formed over the metal film and the metal film is etched using the photoresist film 19 as a mask to form a wiring layer 5. The interlayer insulating film 6b is comprised of a silicon oxide film formed by, for example, CVD. The metal film is comprised of an aluminum film formed by, for example, sputtering. The formed wiring layer 5 comprises the wiring layer 5M3 as the third layer illustrated in FIG. 38.

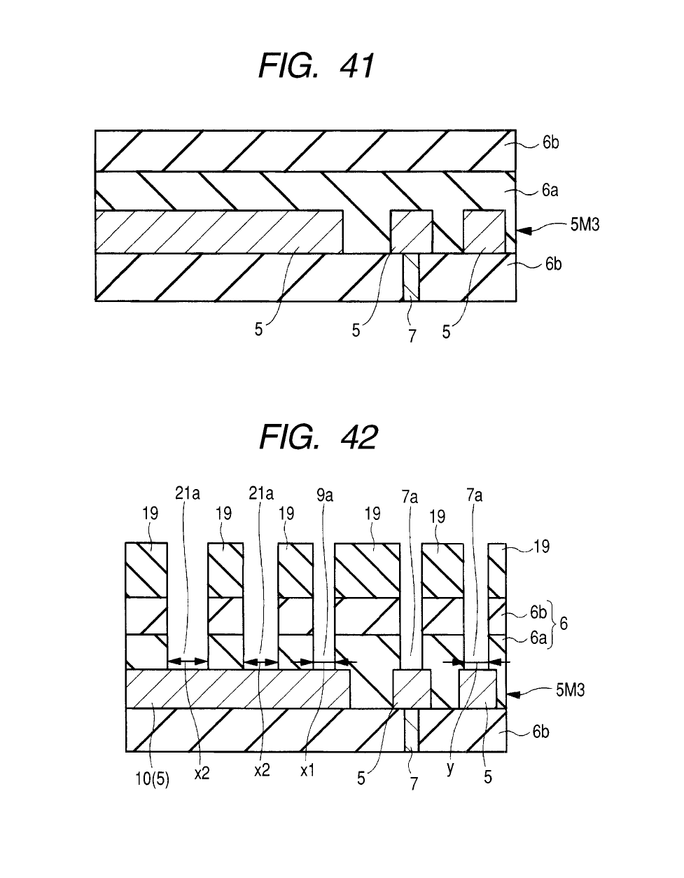

Subsequently, the photoresist film 19 is removed and then an interlayer insulating film 6a is formed so that the gaps in the wiring layer 5M3 as the third layer are filled as illustrated in FIG. 40. Thereafter, the interlayer insulating film 6a is planarized (FIG. 41). The interlayer insulating film 6a may be any insulating film as long as the insulating film is excellent in the property of filling and is comprised of a silicon oxide film formed by, for example, HDP-CVD.

Subsequently, an interlayer insulating film 6b is formed over the interlayer insulating film 6a as illustrated in FIG. 41. The interlayer insulating film 6b is comprised of a silicon oxide film formed by, for example, CVD. The interlayer insulating film 6a and the interlayer insulating film 6b comprise an interlayer insulating film 6. The thickness thereof is adjusted so that the wiring layer 5M3 as the third layer and the wiring layer thereabove are electrically isolated from each other.

Thereafter, as illustrated in FIG. 42, a photoresist film 19 patterned by photolithography is formed over the interlayer insulating film 6. The interlayer insulating film 6 is etched using the photoresist film 19 as a mask to form holes 7a, a trench 9a, and trenches 21a in the interlayer insulating film 6. At this time, adjustment is so made that the width x2 of each trench 21a (the right and left direction in the drawing) is equal to or larger than the width y of each hole 7a and the width x1 of the trench 9a. The trench 9a and the trenches 21a are so formed that the planar shape thereof is ring shape as illustrated in FIG. 37.

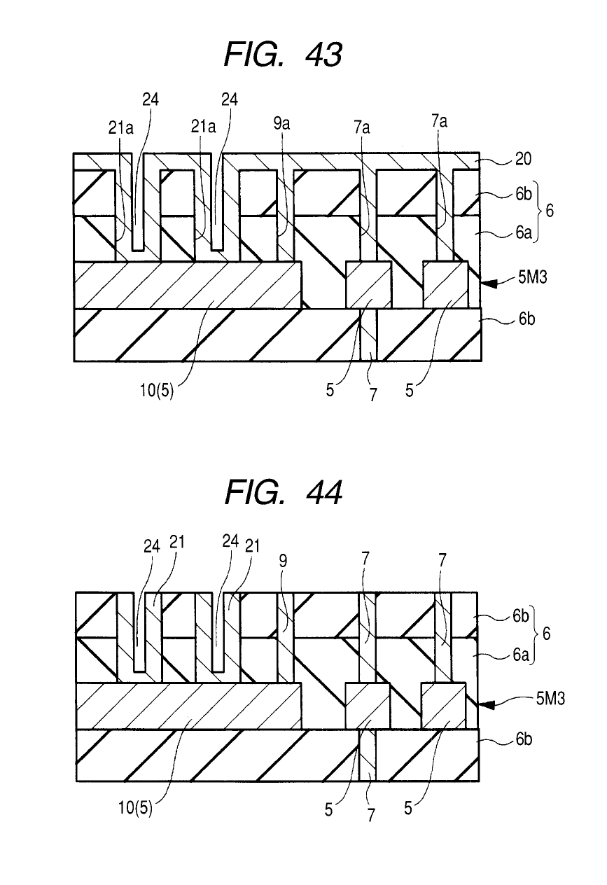

Subsequently the photoresist film 19 is removed and then barrier metal (not shown) is formed on the side walls of the holes 7a, trench 9a, and trenches 21a as illustrated in FIG. 43. A metal film 20 is so formed that the holes 7a and the trench 9a are filled therewith with the barrier metal in-between. The metal film 20 is comprised of a tungsten film of, for example, high-melting point metal. When the width x2 of each trench 21a is equal to or larger than such a film thickness that the metal film 20 fills the interior of the holes 7a and the trench 9a at this time, the air gaps 24 are formed in the trenches 21a.

Subsequently, the superfluous metal film 20 and barrier metal are removed by polishing as illustrated in FIG. 44. As a result, the circuit vias 7 are formed in the holes 7a and the protecting via 9 is formed in the trench 9a, and further the inner vias 21 having the air gaps 24 are formed in the trenches 21a.

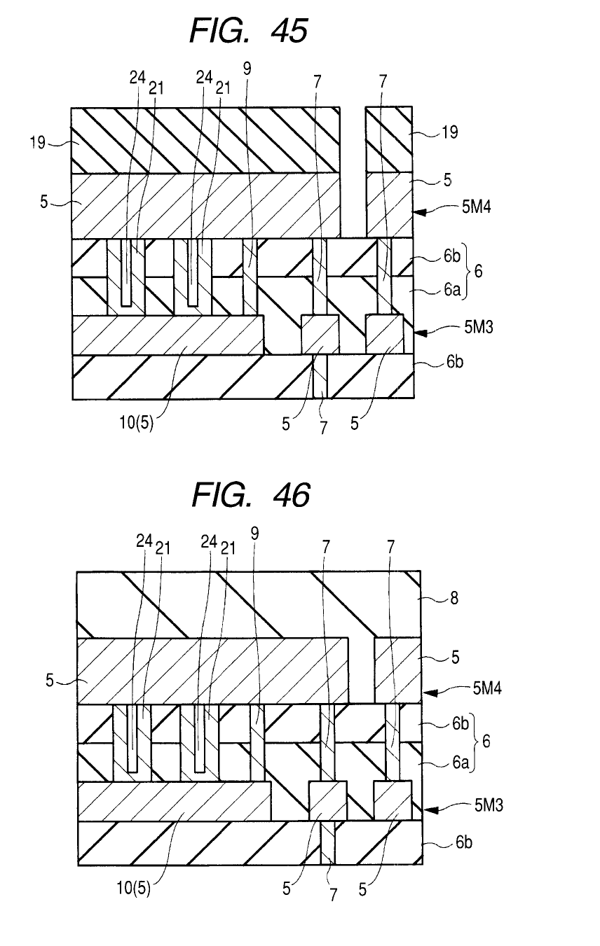

Subsequently, a metal film is formed over the interlayer insulating film 6 in which the circuit vias 7 and the protecting via 9 are formed, as illustrated in FIG. 45. Thereafter, a photoresist film 19 patterned by photolithography is formed over the metal film and the metal film is etched using the photoresist film 19 as a mask to form a wiring layer 5. The metal film is inferior in coverage and is comprised of an aluminum film formed by, for example, sputtering. For this reason, the air gaps 24 in the inner vias 21 are not filled with the metal film but are closed therewith. The formed wiring layer 5 comprises the fourth (uppermost) wiring layer 5M4 illustrated in FIG. 38.

Subsequently, the photoresist film 19 is removed and then a surface protective film 8 is formed so that the gaps in the wiring layer 5M4 as the fourth layer are filled as illustrated in FIG. 46. The surface protective film 8 is comprised of a polyimide film formed by, for example, application. In this embodiment, the surface protective film 8 is of monolayer structure but may be of laminated structure.

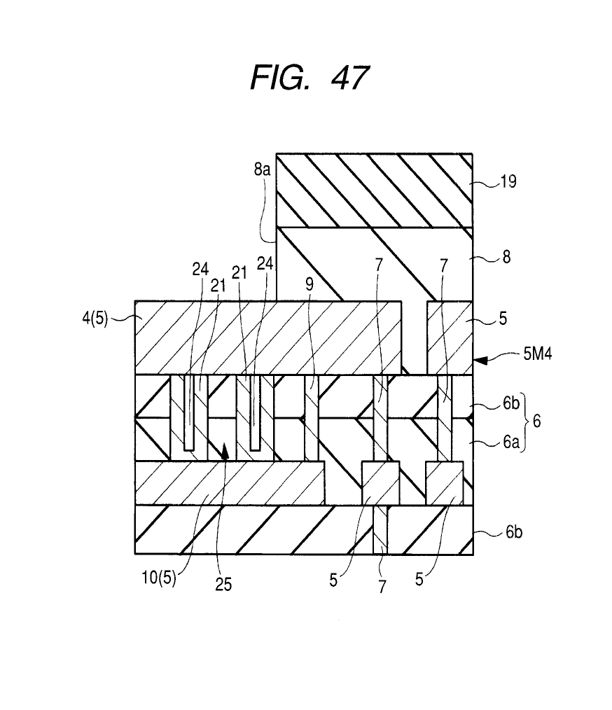

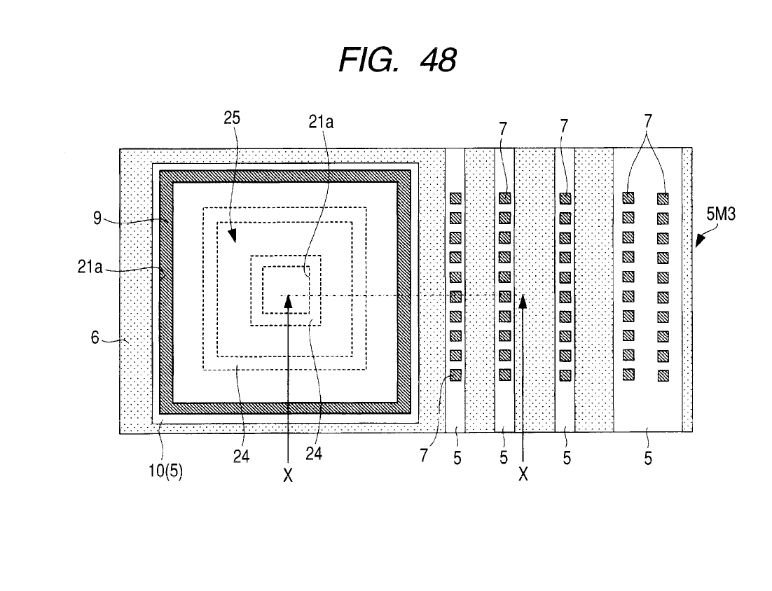

Subsequently, a photoresist film 19 patterned by photolithography is formed over the surface protective film 8 as illustrated in FIG. 47. The surface protective film 8 is etched using the photoresist film 19 as a mask to form a pad opening 8a in the surface protective film 8. Subsequently, the photoresist film 19 is removed to expose part of the wiring layer 5 as the uppermost layer in the pad opening 8a and an electrode pad 4 is thus formed (FIG. 38). As a result, the semiconductor device in this embodiment is finished.

### Ninth Embodiment

As described with reference to FIG. 38, for example, the eighth embodiment is configured as follows: the inner vias 21 and the air gaps 24 are provided in the area of the interlayer insulating film 6 encircled with the protecting via 9 and the protecting wiring layer 10. In the ninth embodiment, only air gaps 24 are provided in the area of the interlayer insulating film 6 encircled with the protecting via 9 and the protecting wiring layer 10 under the electrode pad 4. Hereafter, description will be given with a focus on a difference from the eighth embodiment.

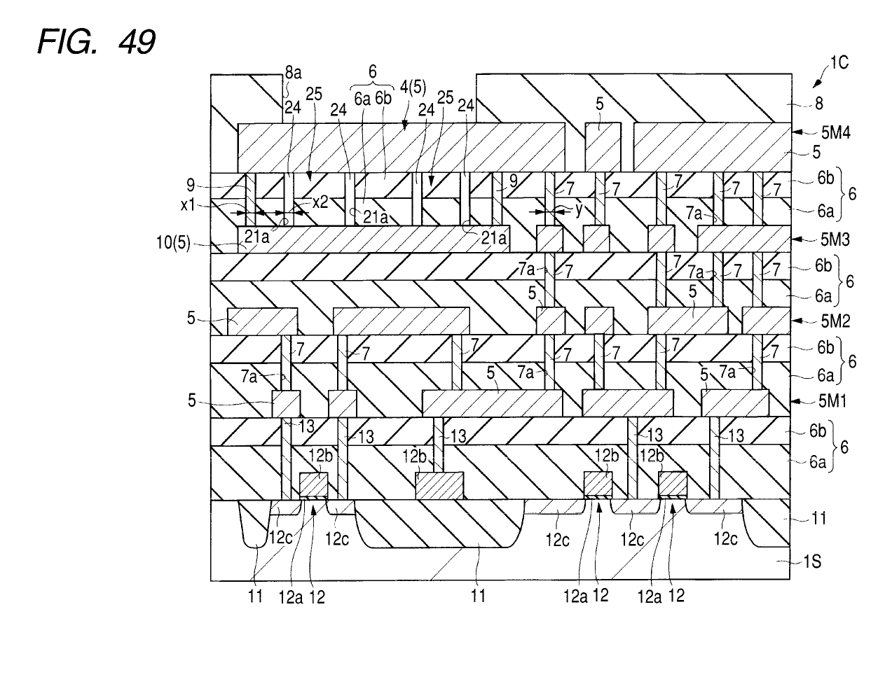

FIG. 48 is a schematic diagram illustrating a plane of a substantial part of a semiconductor device in this embodiment and FIG. 49 is a schematic diagram illustrating the section taken along line X-X of FIG. 48. FIG. 48 is so depicted that the dispositional relation between the protecting via 9 provided over the protecting wiring layer 10 comprised of part of the third wiring layer 5M3 and the air gaps 24 is clarified. Some members are omitted in the drawing.

As illustrated in FIG. 48 and FIG. 49, planar ring-shaped trenches 21a are doubly provided inside the planar ring-shaped protecting via 9 and the trenches 21a are provided therein with an air gap 24. These air gaps 24 are capable of absorbing shock as air cushions, for example, when a probe pin is brought into contact with the electrode pad 4. The portion of the interlayer insulating film 6 between the doubly provided air gaps 24, that is, the buffer region 25 between the air gap 24 and the air gap 24 is reduced in sectional area and is reduced in load resistance. For this reason, when stress is too great for the air gaps 24 to resist as air cushions, the stress can be absorbed by letting cracking (destruction) occur in the buffer region 25. In this embodiment, no metal film is deposited in the trenches 21a unlike the eighth embodiment; therefore, the air gaps are capable of absorbing more stress as air cushions.

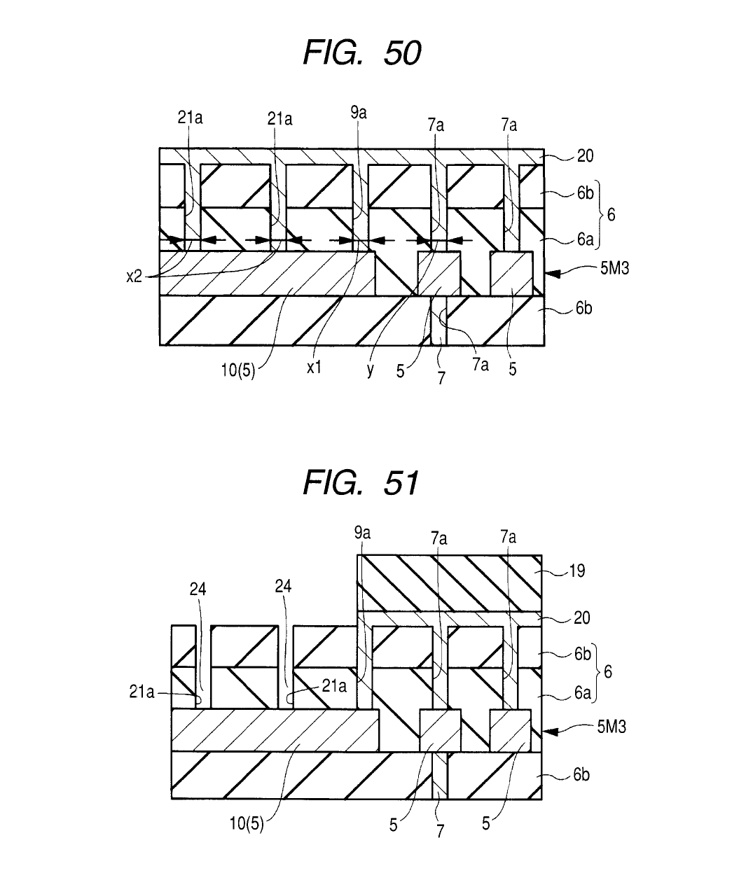

Description will be given to a manufacturing method for the semiconductor device in this embodiment step by step with reference to FIG. 50 to FIG. 55. The MISFETs and multiple wiring layers (multiplayer interconnection) comprising the circuit can be manufactured by publicly known techniques. Therefore, the description thereof will be omitted and description will be given with a focus on the formation of the air gaps 24.

As illustrated in FIG. 50, holes 7a, a trench 9a, and trenches 21a are formed in the interlayer insulating film 6 and barrier metal (not shown) is formed on the side walls thereof. Thereafter, a metal film 20 is formed so the holes 7a, trench 9a, and trenches 21a are filled therewith with the barrier metal in-between. The metal film 20 is comprised of a tungsten film of, for example, high-melting point metal. In this embodiment, the following measure is taken when the holes 7a, trench 9a, and trenches 21a are formed: the width y of each hole 7a, the width x1 of the trench 9a, and the width x2 of each trench 21a are made identical with one another. However, the width x1 of the trench 9a and the width x2 of each trench 21a may be larger than the width y of each hole 7a.

Subsequently, a photoresist film 19 patterned by photolithography is formed over the metal film 20 so that the holes 7a and trench 9a filled with the metal film 20 are covered therewith as illustrated in FIG. 51. The metal film 20 is etched using the photoresist film 19 as a mask to form air gaps 24 in the trenches 21a.

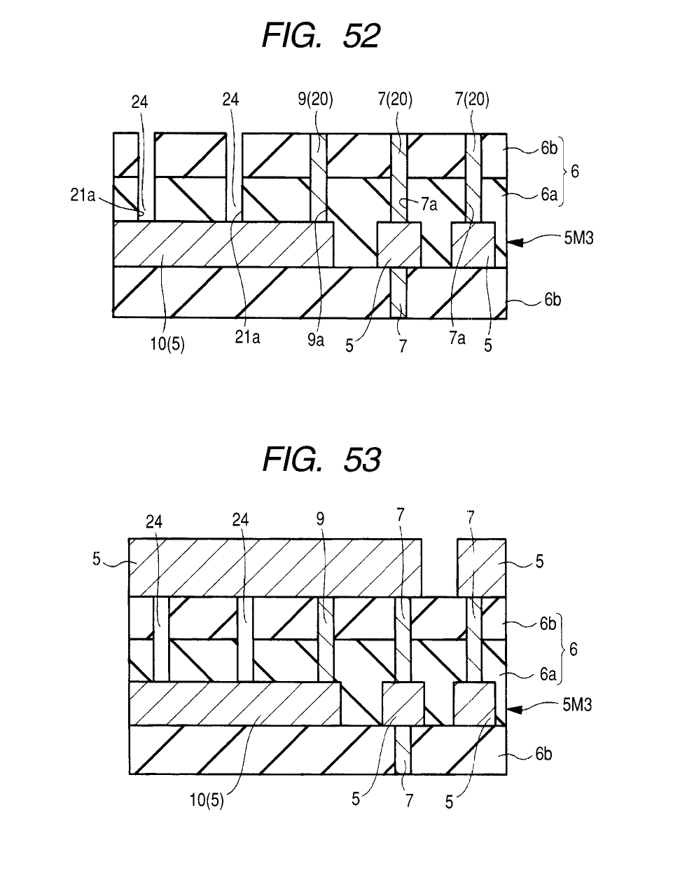

Subsequently, the superfluous metal film 20 and barrier metal are removed by polishing as illustrated in FIG. 52 to form circuit vias 7 in the holes 7a and the protecting via 9 in the trench 9a.

Subsequently, a metal film is formed over the interlayer insulating film 6 in which the circuit vias 7 and the protecting via 9 are formed, as illustrated in FIG. 53. Thereafter, the metal film is etched using photolithography to form a wiring layer 5. The metal film is inferior in coverage and is comprised of an aluminum film formed by, for example, sputtering. For this reason, the air gaps 24 are not filled with the metal film but are closed therewith. The formed wiring layer 5 comprises the fourth (uppermost)) wiring layer 5M4 illustrated in FIG. 49.

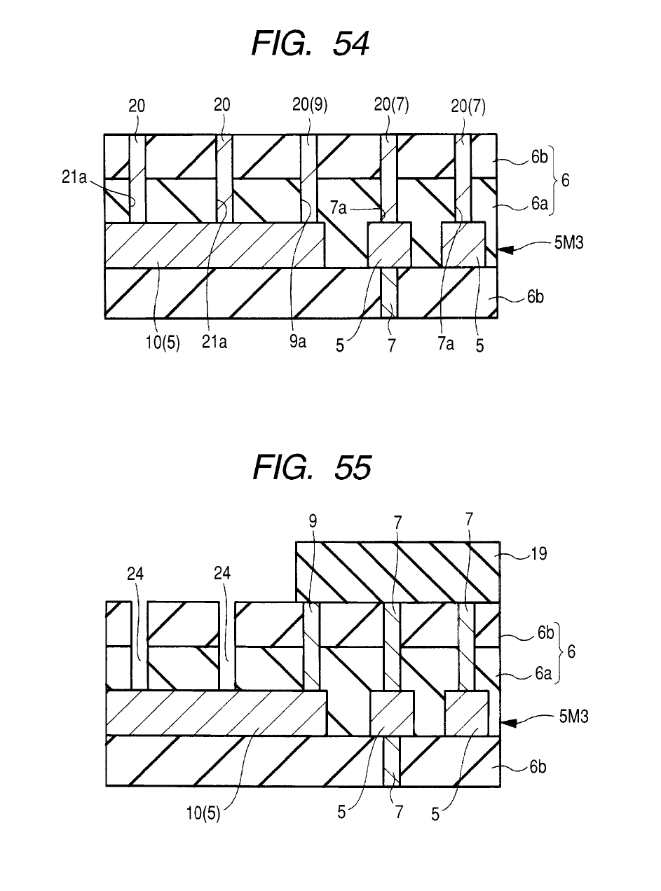

Thereafter, a surface protective film 8 is formed so that the gaps in the wiring layer 5M4 as the fourth layer are filled therewith. Then, the surface protective film 8 is etched using photolithography to form a pad opening 8a in the surface protective film 8. As a result, part of the wiring layer 5 as the uppermost layer is exposed in the pad opening 8a and an electrode pad 4 is formed (FIG. 49). As a result, the semiconductor device in this embodiment is finished. Following the step illustrated in FIG. 50, the steps illustrated in FIG. 54 and FIG. 55 may be carried out.

The superfluous metal film 20 and barrier metal are removed by polishing as illustrated in FIG. 54 to fill the holes 7a, trench 9a, and trenches 21a with the metal film 20. As a result, the circuit vias 7 are formed in the holes 7a and the protecting via 9 is formed in the trench 9a.

Subsequently, a photoresist film 19 patterned by photolithography is formed over the interlayer insulating film 6 so that the holes 7a and trench 9a filled with the metal film 20 are covered therewith as illustrated in FIG. 55. Then, the metal film 20 in the trenches 21a is etched using the photoresist film 19 as a mask to form air gaps 24 in the trenches 21a. The subsequent steps are as described with reference to FIG. 53 and FIG. 49. The semiconductor device in this embodiment is also finished by these steps.

### 10th Embodiment

As described with reference to FIG. 38, for example, the eighth embodiment is configured as follows: the inner vias 21 and the air gaps 24 are provided in the area of the interlayer insulating film 6 encircled with the protecting via 9 and the protecting wiring layer 10. In the 10th embodiment, inner wiring layers 26 having an air gap 24 are provided in the area of the interlayer insulating film 6 encircled with the protecting vias 9, 23, protecting wiring layer 10, and intermediate layer 22 under the electrode pad 4. Hereafter, description will be given with a focus on a difference from the eighth embodiment.

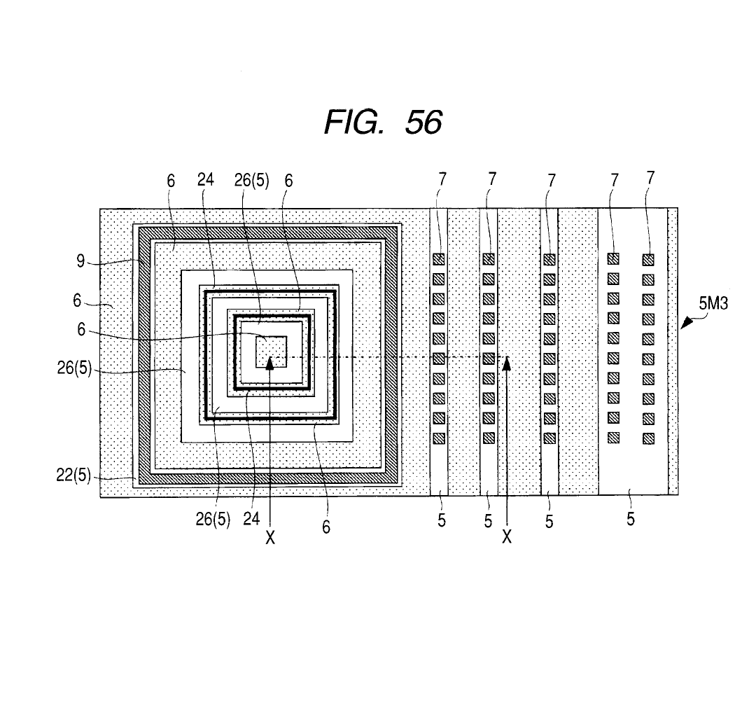

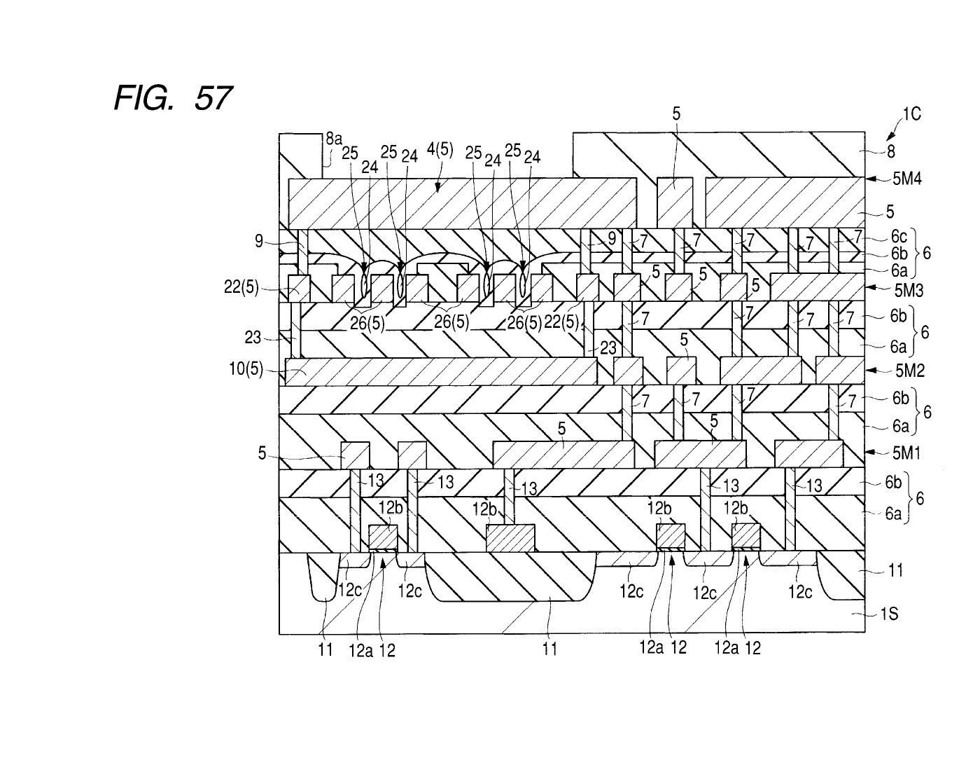

FIG. 56 is a schematic diagram illustrating a plane of a substantial part of a semiconductor device in this embodiment and FIG. 57 is a schematic diagram illustrating the section taken along line X-X of FIG. 56. FIG. 56 is so depicted that the dispositional relation between the following is clarified: the intermediate layer 22 and inner wiring layer 26 comprised of part of the third wiring layer 5M3; the protecting via 9 provided over the intermediate layer 22; and the air gaps 24. Some members are omitted in the drawing.

As illustrated in FIG. 56 and FIG. 57, the planar ring-shaped inner wiring layer 26 is triply provided inside the planar ring-shaped intermediate layer 22. Between the inner wiring layers 26, there are provided air gaps 24 formed by the interlayer insulating film 6. The inner wiring layers 26 are electrically isolated from the other wiring layers 5 and can be said to be independent rings. The air gaps 24 are capable of absorbing shock as air cushions, for example, when a probe pin is brought into contact with the electrode pad 4. Buffer regions 25 are provided in the interlayer insulating film 6 over the air gaps 24. Specifically, an interlayer insulating film 6 and an interlayer insulating film 6 are brought into contact with each other to close the air gaps 24 and the buffer regions 25 are formed there. The buffer regions 25 are boundaries of the interlayer insulating film 6 and thus low in load resistance. For this reason, when stress is too great for the air gaps 24 to resist as air cushions, the stress can be absorbed by letting cracking (destruction) occur in the buffer regions 25.

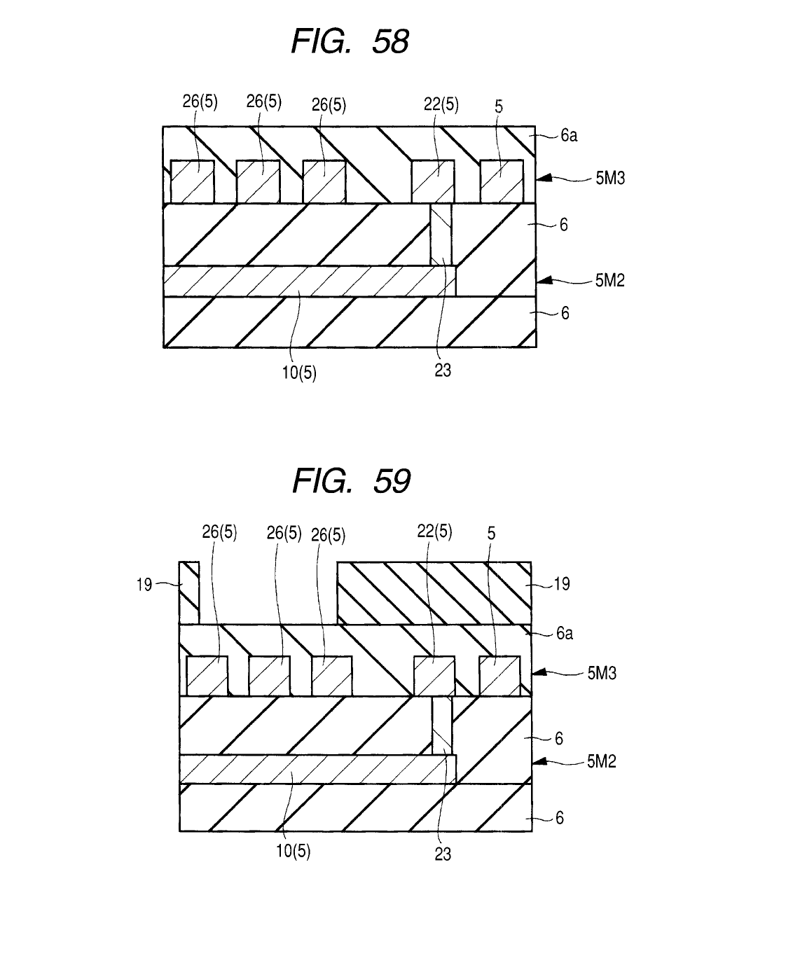

Description will be given to a manufacturing method for the semiconductor device in this embodiment step by step with reference to FIG. 58 to FIG. 62. The MISFETs and multiple wiring layers (multiplayer interconnection) comprising the circuit can be manufactured by publicly known techniques. Therefore, the description thereof will be omitted and description will be given with a focus on the formation of the air gaps 24.

As illustrated in FIG. 58, the protecting wiring layer 10 comprised of the wiring layer 5M2 as the second wiring layer 5 is covered with the interlayer insulating film 6, and the protecting via 23 is formed over the protecting wiring layer 10. A metal film comprising the wiring layer 5M3 as the third layer is formed over the interlayer insulating film 6. Then, the metal film is patterned using photolithography to form a wiring layer 5, an intermediate layer 22, and inner wiring layers 26. The metal film is comprised of an aluminum film formed by, for example, sputtering. An interlayer insulating film 6a is formed so that the gaps in the wiring layer 5M3 as the third layer are filled and then the interlayer insulating film 6a is planarized. The interlayer insulating film 6a may be any insulating film as long as the insulating film is excellent in the property of filling and is comprised of a silicon oxide film formed by, for example, HDP-CVD.

Subsequently a photoresist film 19 patterned by photolithography is formed over the interlayer insulating film 6a as illustrated in FIG. 59. Then, etching is carried out using photoresist film 19 as a mask to remove the interlayer insulating film 6a from between the inner wiring layers 26. As illustrated in FIG. 59, additionally, the interlayer insulating film 6 under the side walls of the inner wiring layers 26 may be overetched.

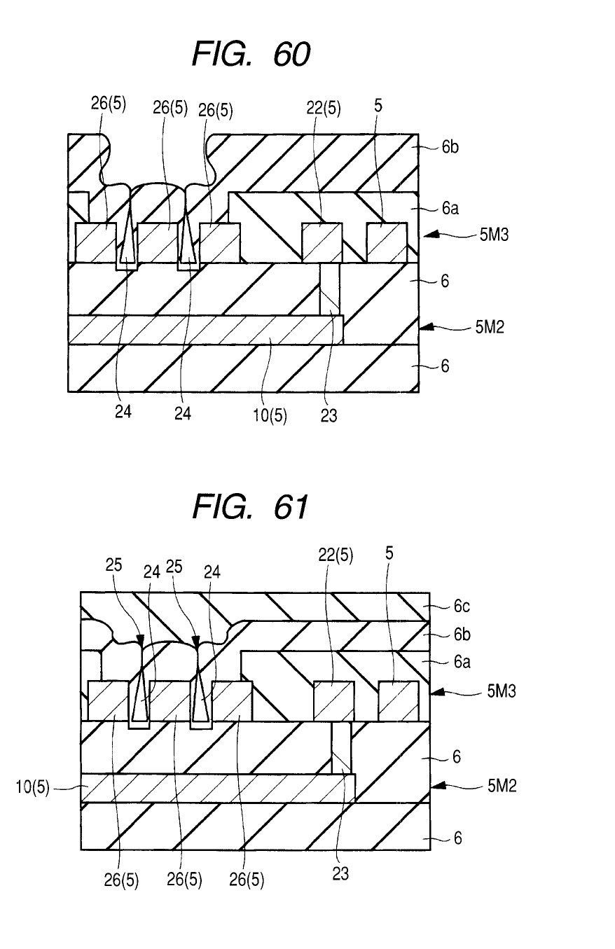

Subsequently, the photoresist film 19 is removed and then an interlayer insulating film 6b is formed so that the interlayer insulating film 6a is covered as illustrated in FIG. 60. This interlayer insulating film 6b is comprised of a silicon oxide film formed by, for example, CVD and is lower in the property of filling than the interlayer insulating film 6a. For this reason, air gaps 24 closed with the interlayer insulating film 6b are formed between the inner wiring layers 26.

Subsequently, the upper part of the interlayer insulating film 6b is removed by polishing and then an interlayer insulating film 6c is formed over the interlayer insulating film 6b as illustrated in FIG. 61. The interlayer insulating film 6c is comprised of a silicon oxide film formed by, for example, CVD.

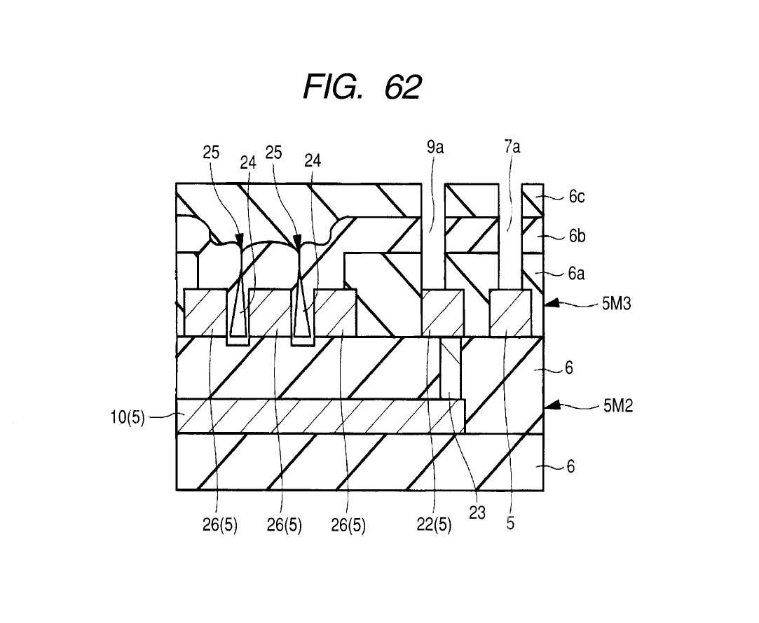

Subsequently, holes 7a and a trench 9a are formed in the interlayer insulating films 6a, 6b, 6c using photolithography as illustrated in FIG. 62.

Thereafter, circuit vias 7 are formed in the holes 7a and a protecting via 9 is formed in the trench 9a as illustrated in FIG. 57. A metal film is formed over the interlayer insulating film 6 with the circuit vias 7 and protecting via 9 formed therein. Then, the metal film is etched using photolithography to form a wiring layer 5M4 as the fourth layer (uppermost layer). Subsequently, a surface protective film 8 is formed so that the gaps in the wiring layer 5M4 are filled and the surface protective film 8 is etched by photolithography to form a pad opening 8a in the surface protective film 8. As a result, part of the wiring layer 5 as the uppermost layer is exposed in the pad opening 8a to form an electrode pad 4 and the semiconductor device in this embodiment is finished.

### 11th Embodiment

In the description of the first to 10th embodiments, wiring predominantly composed of aluminum has been taken as examples. In the description of this embodiment, a case where wiring predominantly composed of copper is included will be taken as an example.

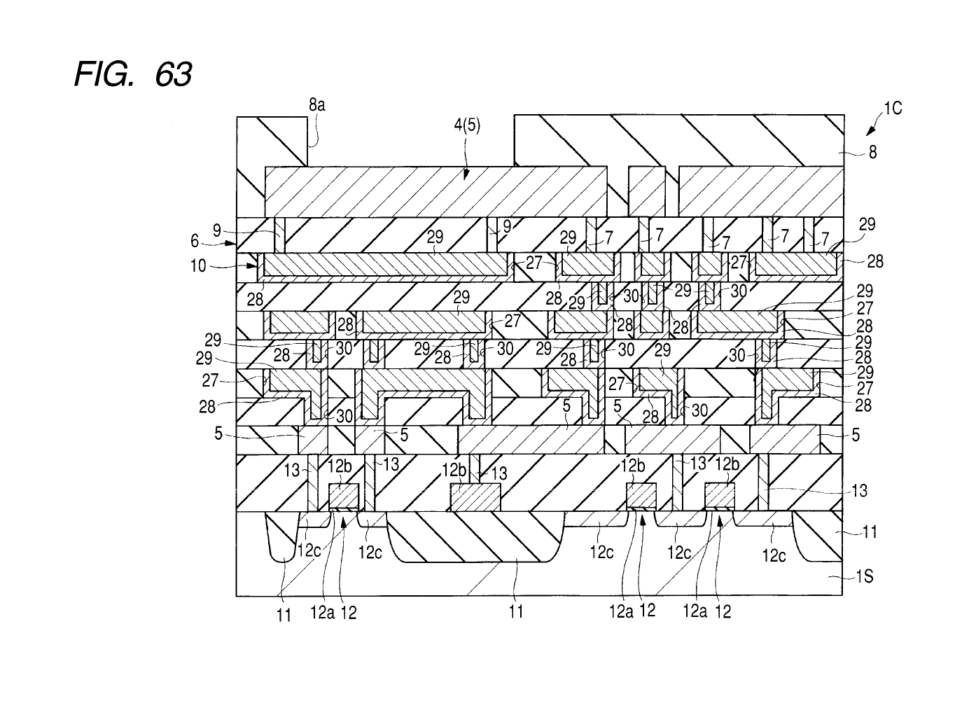

As illustrated in FIG. 63, upper wiring layers can be formed by filling trenches 27 formed in an interlayer insulating film 6 with a barrier metal film 28 and a material film 29 predominantly composed of copper formed over the barrier metal film 28. Plugs are also similarly formed by filling holes 30 formed in the interlayer insulating film 6 with the barrier metal film 28 and the material film 29. For the material for forming the barrier metal film 28, the following can be used: a high-melting point metal film of tantalum, tantalum nitride, titanium, or titanium nitride or a laminated film of them.

Upper wiring layers are formed by forming the trenches 27 and the holes 30 and then filling them with the barrier metal film 28 and the material film 29.

In the description of the above embodiments, a silicon oxide film has been taken as an example of the interlayer insulating film 6. However, the invention is not limited to this and a material lower in dielectric constant than the silicon oxide film may be used. For example, a material whose relative dielectric constant is equal to or lower than that (approximately, 4.2) of TEOS oxide films may be used. Examples of such materials include organic materials, SiOC materials, and SiOF materials. Possible methods for the formation of these films include CVD and methods of application.

In this embodiment, the same effect as in the first to 10th embodiments can be obtained even when such wiring layers and interlayer insulating films are used.

### 12th Embodiment

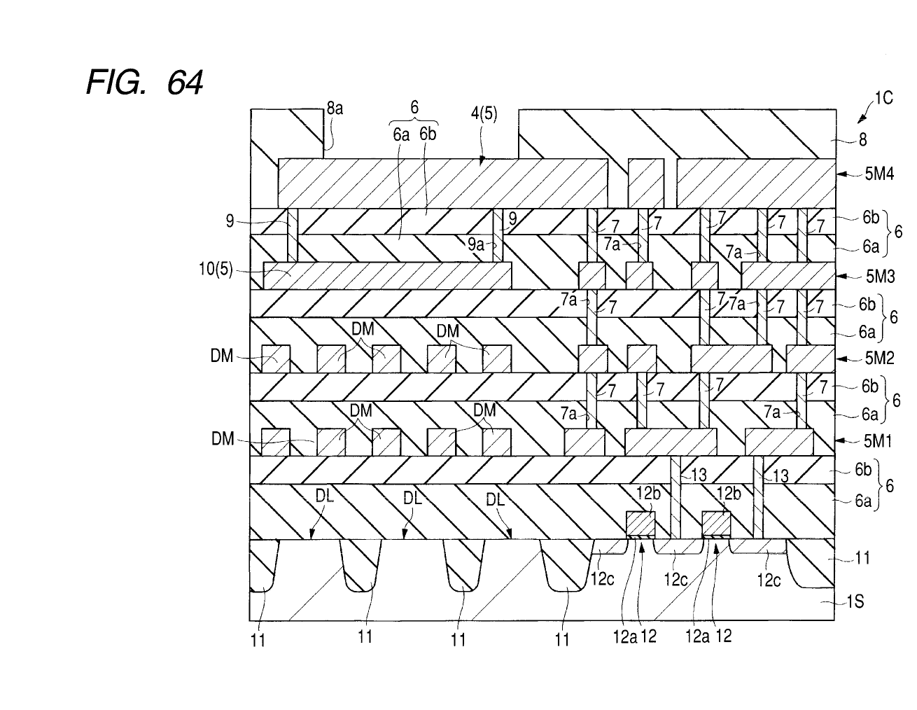

In the description of the first to 11th embodiments, cases where such semiconductor elements as MISFETs 12 and wiring layers 5 are formed in an active area positioned under the electrode pad 4 have been taken as examples. In the description of this embodiment, a case where a dummy active area DL and a dummy wiring DM are formed as illustrated in FIG. 64 will be taken as an example.

The dummy active areas DL illustrated in FIG. 64 are not provided with a semiconductor element. When the element isolation regions 11 are formed by the STI described in relation to the first embodiment, STI in a large pattern can be reduced by forming such dummy active areas DL. Therefore, a problem of dishing or the like does not arise and the planarity of semiconductor chips can be enhanced.

The above advantages are obtained not only by the configuration that the dummy active areas DL are not provided with a semiconductor element. For example, a dummy element that is not coupled with such a circuit as described in relation to the first embodiment and does not contribute to the circuitry may be provided.

When a wiring layer 5 is not provided under the electrode pad 4, aside from the protecting wiring layer 10, dummy wirings DM can be provided under the electrode pad 4 and the protecting wiring layer 10 as illustrated in FIG. 64. In this case, the dummy wirings DM are dummy wirings that do not contribute to the circuitry. That is, the dummy wirings DM are wirings that are not electrically coupled with the above-mentioned MISFETs 12. The provision of these dummy wirings DM makes it possible to enhance the planarity between wiring layers.

Special consideration will be given to a case where a dummy active area DL is formed. Since the dummy active area DL does not contribute to the circuitry, it may be unnecessary to form a wiring layer 5. However, the planarity of interlayer insulating films is enhanced by providing the above-mentioned dummy wiring DM above the dummy active area DL.

The above-mentioned dummy active area DL and dummy wiring DM are applicable to the first to 11th embodiments.

Up to this point, concrete description has been given to the invention made by the present inventors based on embodiments of the invention. The invention is not limited to the above-mentioned embodiments and can be variously modified without departing from the subject matter of the invention, needless to add.

In the description of the above embodiments, for example, cases where the invention is applied to wiring layers in four layers. The invention is not limited to this and can also be applied to multiple wiring layers.

The invention can be widely utilized for semiconductor devices, in particular, for the manufacturing industry of semiconductor devices in which an electrode pad is provided above a semiconductor element.

1-19. (canceled)

20. A semiconductor device comprising:
a semiconductor substrate;
a semiconductor element formed over the semiconductor substrate;
a plurality of wiring layers formed over the semiconductor element and electrically coupled with the semiconductor element;
an interlayer insulating film formed over the wiring layers;
a first via formed in the interlayer insulating film and coupled with the wiring layers;
a first wiring formed in the interlayer insulating film and coupled with the first via;
a second via formed in the interlayer insulating film and coupled with the first wiring;
a second wiring formed in the interlayer insulating film;
a third via having a planar ring shape, formed in the interlayer insulating film and coupled with the second wiring;
an electrode pad formed over the interlayer insulating film and coupled with the second via and the third via;
an insulating film formed over the interlayer insulating film so as to cover the electrode pad; and
an opening formed in the insulating film such that a part of the electrode is exposed from the opening,
wherein a part of the interlayer insulating film is encircled with the third via and the second wiring under the opening,
wherein a planar area of the second wiring is larger than a planar area of the opening,
wherein a width of the third via is larger than a width of the second via,
wherein, in a planar view, an inner wall of the third via is arranged outside of the opening, and
wherein the planar shape of the third via has at least eight corners.

21. The semiconductor device according to the claim 20,
wherein a planar area encircled with the third via in the planar ring shape is larger than a planar area of the opening.

22. The semiconductor device according to the claim 21,
wherein a planar area encircled with the third via in the planar ring shape is smaller than a planar area of the second wiring.

23. The semiconductor device according to the claim 20,
wherein the semiconductor element is overlapped with the electrode pad in planar view.

24. The semiconductor device according to the claim 20,
wherein the second wiring is formed at the same layer as the first wiring,
wherein the third via is formed at the same layer as the second via, and
wherein the electrode pad is formed at the uppermost wiring layer.

25. The semiconductor device according to the claim 20,
wherein, in planar view, the third via is formed between an edge of the semiconductor substrate and the second via.

26. The semiconductor device according to the claim 20,
wherein a crack of the interlayer insulating film generated within the opening in planar view is confined to a region defined by the third via and the second wiring so as not to extend to the second via or the first wiring.

27. The semiconductor device according to the claim 20,
wherein the electrode pad within the opening has a first region for a bonding wire and a second region for a probe test.

28. The semiconductor device according to the claim 20,
wherein the electrode pad includes an aluminum film, and
wherein the third via includes a tungsten film.
